(19) United States
(12) Patent Application Publication
(10) Pub. No.: US 2026/0359519 A1
(43) Pub. Date: Nov. 12, 2026

(54) CONVOLUTION-HIERARCHICAL DEEP- LEARNING NEURAL NETWORK (C-HIDENN) FOR FAST AND ACCURATE PDE SOLVER AND TRAINER AND APPLICATIONS OF SAME

(71) Applicant: NORTHWESTERN UNIVERSITY, Evanston, IL (US)

(72) Inventors: Wing Kam Liu, Oak Brook, IL (US); Ye Lu, Evanston, IL (US); Hengyang Li, Evanston, IL (US); Chanwook Park, Evanston, IL (US); Satyajit Mojumder, Evanston, IL (US); Sourav Saha, Evanston, IL (US); Xiaoyu Xie, Evanston, IL (US)

(21) Appl. No.: 19/110,137

(22) PCT Filed: Sep. 18, 2023
(86) PCT No.: PCT/US2023/032980

§ 371 Date: Mar. 10, 2025

Related U.S. Application Data
(60) Provisional application No. 63/407,444, filed on Sep. 16, 2022.

(51) Int. Cl. G06F 30/27; G06F 30/28

(52) U.S. Cl. CPC G06F 30/27; G06F 30/28

(57) ABSTRACT

Convolution-Hierarchical Deep-learning Neural Network (C-HiDeNN) is a customized neural network that can solve and train partial differential equations for various Computational Science and Engineering (CS&E) problems including but not limited to linear/nonlinear solid mechanics problems, damage/fracture problems, thermal and fluid problems, multiphysics and multiscale problems, and many more. Compared to classical numerical methods such as Finite Element Analysis (FEA), C-HiDeNN is much more accurate and faster due to the architecture of hierarchical deep neural networks (DNNs) with convolution layers. The training of C-HiDeNN renders versatile local and global mesh adaptivity which further improves the efficiency of the numerical method.

### CROSS-REFERENCE TO RELATED PATENT APPLICATION

This application claims priority to and the benefit of U.S. Provisional Patent Application Ser. No. 63/407,444, filed Sep. 16, 2022, which is incorporated herein in its entirety by reference.

### FIELD OF INVENTION

The present disclosure relates to the technical field of Convolution-Hierarchical Deep-learning Neural Network (C-HiDeNN) which pertains to a method, algorithm, and computer program employed in engineering analysis such as linear/nonlinear solid mechanics, damage, fracture, fatigue, dynamics, thermal, fluid, Multiphysics, and multiscale analysis.

### BACKGROUND OF THE INVENTION

The background description provided herein is for the purpose of generally presenting the context of the present invention. The subject matter discussed in the background of the invention section should not be assumed to be prior art merely as a result of its mention in the background of the invention section.

The field of computational science and engineering is currently undergoing a paradigm shift in terms of algorithms and software. Computational scientists are developing methods that rely on training neural networks using experimental or computational data. Andrej Karpathy coined this new generation of software as ‘Software 2.0’. In Software 1.0, developers are required to specify the problem, design algorithms, and break down complex tasks into smaller components. However, in Software 2.0, developers utilize data to design optimization problems and train neural networks to solve a wide range of problems.

The field of engineering analysis is undergoing a similar evolution, transitioning from classical numerical methods like finite element analysis (FEA), which solves systems of linear equations, to methods based on physics-informed neural networks (PINNs) that solve optimization problems; namely, the transition from ‘Engineering Software 1.0’ to ‘Engineering Software 2.0’. The key advantage of utilizing software 2.0 lies in the application of automatic differentiation to minimize the Lagrangian form of any governing equations. Since the pioneering work reported in 2017, fully connected PINNs for solving forward and inverse partial differential equations (PDEs) have experienced a resurgence. PINNs have found applications in various domains of engineering analysis, encompassing solid mechanics, fluid dynamics, thermal analysis, and Multiphysics simulations.

Despite rapid advancements and significant achievements, fully connected PINNs have certain limitations: 1) the training cost is prohibitively expensive, and 2) the direct enforcement of initial/boundary conditions poses challenges. To enhance training efficiency, convolutional neural network (CNN)-based PINNs were introduced. Unlike fully connected PINNs, where all neurons influence each other, CNN-based PINNs restrict the number of neurons that impact a single neuron, leading to a substantial reduction in trainable weights and biases. However, most CNN-based approaches rely on regular and structured uniform grids since CNNs are inherently designed for rectangular grids in Cartesian coordinates. This restricts the applicability of CNN-based PINNs to complex geometries. To address this grid-related issue, a graph convolutional network (GCN) is proposed as a solution. In GCN, the traditional convolutional layer is replaced with graph neural networks that can effectively handle both structured and unstructured grids.

There remain two unresolved challenges in the transition from fully connected PINNs to Graph Convolutional Network (GCN)-based PINNs. Firstly, the efficiency of these approaches still lags classical numerical methods like Finite Element Analysis (FEA). In PINN, regardless of their structure, all neural network weights and biases are trainable and mostly initialized randomly. Conversely, FEA utilizes predefined functional approximations employing Lagrange interpolating polynomials. Secondly, ensuring strict adherence to initial and boundary conditions poses an ongoing challenge since they are predominantly imposed indirectly as constraints through Lagrangian methods.

Therefore, it is desirable to develop a systematically constructed neural network architecture that takes advantage of well-developed FEA or meshfree theories to enhance computational efficiency, while keeping the benefit of GCNs to handle unstructured grid needed for problems with complex geometry.

### SUMMARY OF INVENTION

In light of the foregoing, this invention discloses a forward engineering analysis method of Convolution-Hierarchical Deep-learning Neural Network (C-HiDeNN) comprises providing a Hierarchical Deep-learning Neural Network-Finite Element Method (HiDeNN-FEM) function; obtaining a convolution patch function; integrating the convolution patch function with the HiDeNN-FEM function to generate a C-HiDeNN interpolant; and obtaining an optimization problem with a physics-based loss function using the C-HiDeNN interpolant; resolving the optimization problem with an optimization algorithms or at least one matrix solver; wherein linear interpolation space of the HiDeNN-FEM function is expanded to non-linear or arbitrary functions.

In one embodiment, the step of resolving the optimization problem comprises training the optimization problem with the optimization algorithm or the at least one matrix solver.

In one embodiment, the step of resolving the optimization problem comprises solving the optimization problem with the optimization algorithm or the at least one matrix solver.

In one embodiment, the HiDeNN-FEM function is a custom-designed neural network having a mathematical form, wherein the mathematical form comprises a partition of unity (POU)-FEM or a POU-meshfree method.

In one embodiment, the convolution patch function is computed via a meshfree technique. In one embodiment, the meshfree technique comprises at least one of reproducing kernel element method (RKEM), hierarchical enrichment, radial point interpolation method (RPIM), and reproducing kernel peridynamics.

In one embodiment, the convolution patch function is obtained according to nodal connectivity and a calculation parameter.

In one embodiment, the nodal connectivity is computed using graph theory.

In one embodiment, the calculation parameter comprises a patch size s, a dilation parameter a, and reproducing order p.

In one embodiment, the patch size s is a positive integer and is greater than or equal to p/2.

In one embodiment, the dilation parameter a is a positive real number [symbol] ⁺.

In one embodiment, the reproducing order p is a positive integer.

In one embodiment, the computation of the HiDeNN-FEM function, convolution patch function, C-HiDeNN interpolants are parallelizable.

In one embodiment, the optimization algorithms and matrix solvers are parallelizable.

In yet another embodiment of the invention, a method for graphics processing units (GPU) programming of Convolution-Hierarchical Deep-learning Neural Network (C-HiDeNN) comprises (1) providing a mesh to obtain a Hierarchical Deep-learning Neural Network-Finite Element Method (HiDeNN-FEM) interpolant based on the mesh; (2) computing an elemental patch information and a nodal connectivity based on the mesh and graph theory; (3) computing an assembled moment matrix G using elemental patch information and a calculation parameter; (4) obtaining a convolutional patch function based on the steps (2) and (3); (5) integrating the convolution patch function with the HiDeNN-FEM interpolant obtained in the step (1) to generate a C-HiDeNN interpolant; (6) building a global linear system of equations Ax=b using the C-HiDeNN interpolant; and (7) solving the global linear system of equations using a matrix solver.

In one embodiment, the step (2) is accelerated with a sparse matrix programming library.

In one embodiment, the steps (1) and (3)-(7) are parallelized.

In one embodiment, the steps (3)-(6) are serially conducted and stacked in a GPU memory having a memory limit; wherein the parallelized steps (3)-(6) comprises at least one variables having a variable size; and wherein when the variable size exceeding the memory limit of GPU, the steps (3)-(6) are serially conducted and stacked in a CPU memory.

In one embodiment, the global linear system of equations in step (6) is obtained by linearizing a weak-form of a partial differential equation.

In yet another aspect of the invention, a non-transitory tangible computer readable medium storing a program which, when executed by one or more processors, causes a computer to execute a process for forward engineering analysis using Convolution-Hierarchical Deep-learning Neural Network (C-HiDeNN), the process comprises providing a Hierarchical Deep-learning Neural Network-Finite Element Method (HiDeNN-FEM) function; obtaining a convolution patch function;

integrating the convolution patch function with the HiDeNN-FEM function to generate C-HiDeNN interpolants; and obtaining an iterative solver using the C-HiDeNN interpolants; wherein linear interpolation space of the HiDeNN-FEM function is expanded to non-linear or arbitrary functions.

In one embodiment, the convolution patch function is controlled by a patch size s, a dilation parameter a, and reproducing order p.

In yet another aspect of the invention, a non-transitory tangible computer readable medium storing a program which, when executed by one or more processors, causes a computer to execute a process for GPU acceleration with JAX library using Convolution-Hierarchical Deep-learning Neural Network (C-HiDeNN), the process comprises (1) providing a mesh to obtain a Hierarchical Deep-learning Neural Network-Finite Element Method (HiDeNN-FEM) interpolant based on the mesh; (2) computing an elemental patch information and a nodal connectivity based on the mesh and graph theory; (3) computing an assembled moment matrix G using elemental patch information and a calculation parameter; (4) obtaining a convolutional patch function based on the steps (2) and (3); (5) integrating the convolution patch function with the HiDeNN-FEM interpolant obtained in the step (1) to generate a C-HiDeNN interpolant; (6) building a global linear system of equations Ax=b using the C-HiDeNN interpolant; and (7) solving the global linear system of equations using a matrix solver.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment.

FIG. 1 illustrates an overview of C-HiDeNN theory and computational implementation with potential application areas in the engineering analysis.

FIG. 2 illustrates HiDeNN-FEM formulation for a 1-D Poisson's problem.

FIG. 3 illustrates the nodal patch domain

$$( {A}_{s}^{i} )$$

on a 2-D, 8×8 element mesh. s is the patch size and the domains are colored by the patch size.

FIG. 4 illustrates (a) a labeled graph of five nodes (aka vertices) and their connectivity relationships displayed with edges; (b) an adjacency matrix based on a 4×4 elements (or 5×5 nodes) uniform mesh; and (c) the first row of A² where we can see components 0, 1, 2, 5, 6, 7, 10, 11, and 12 are non-zero.

FIG. 5 illustrates C-HiDeNN formulation for a 1-D Poisson's problem.

FIG. 6 illustrates C-HiDeNN shape function of element er for 2-D 4-node (a) and 3-D 8-node (b) elements.

FIG. 7 illustrates a flowchart of C-HiDeNN.

FIG. 8 illustrates a comparison between FEM (a-c) and C-HiDeNN-FEM (d-f) with different polynomial orders (p=1,2,4).

FIG. 9 illustrates body force (a) and resulting field variable (b) of the 2-D Poisson's problem.

FIG. 10 illustrates convergence plots for uniform meshes.

FIG. 11 illustrates convergence plots for non-uniform meshes.

FIG. 12 illustrates H1 norm error vs. computation time plots for a 2-D Poisson's problem.

FIG. 13 illustrates C¹ C-HiDeNN interpolant and comparison to FE approximation.

FIG. 14 illustrates C-HiDeNN developed for 2-D linear elasticity, and the Cook's membrane problem is solved with plane strain condition and Poisson ratio v=0.4999.

FIG. 15 illustrates locking behavior of C-HiDeNN with 3-D meshes.

FIG. 16 illustrates computation time plots for a 2-D linear elastic problem, Cook's membrane.

FIG. 17 illustrates the effect of automatic node adaptivity of C-HiDeNN by solving a 2-D stress concentration problem.

FIG. 18 illustrates 3-D hyperelasticity problem solved by FEM and C-HiDeNN.

FIG. 19 illustrates 1-D Linear elastic problem with material discontinuity solved by C-HiDeNN.

FIG. 20 illustrates the comparison between a feed forward neural network (FFNN) and a piecewise neural network for resgressing a dataset.

FIG. 21 illustrates the three steps for C-HiDeNN-Graph Neural Network (GNN).

### DETAILED DESCRIPTION OF THE INVENTION

The invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this invention will be thorough and complete, and will fully convey the scope of the invention to those skilled in the art. Like reference numerals refer to like elements throughout.

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

One of ordinary skill in the art will appreciate that starting materials, biological materials, reagents, synthetic methods, purification methods, analytical methods, assay methods, and biological methods other than those specifically exemplified can be employed in the practice of the invention without resort to undue experimentation. All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the invention has been specifically disclosed by preferred embodiments and optional features, modification and variation of the concepts herein disclosed may be resorted to by those skilled in the art, and that such modifications and variations are considered to be within the scope of this invention as defined by the appended claims.

Whenever a range is given in the specification, for example, a temperature range, a time range, or a composition or concentration range, all intermediate ranges and subranges, as well as all individual values included in the ranges given are intended to be included in the invention. It will be understood that any subranges or individual values in a range or subrange that are included in the description herein can be excluded from the claims herein.

It will be understood that, as used in the description herein and throughout the claims that follow, the meaning of “a”, “an”, and “the” includes plural reference unless the context clearly dictates otherwise. Thus, for example, reference to “a cell” includes a plurality of such cells and equivalents thereof known to those skilled in the art. As well, the terms “a” (or “an”), “one or more” and “at least one” can be used interchangeably herein. It is also to be noted that the terms “comprising”, “including”, and “having” can be used interchangeably.

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Furthermore, relative terms, such as “lower” or “bottom” and “upper” or “top,” may be used herein to describe one element's relationship to another element as illustrated in the Fig. s. It will be understood that relative terms are intended to encompass different orientations of the device in addition to the orientation depicted in the Fig. s. For example, if the device in one of the Fig. s is turned over, elements described as being on the “lower” side of other elements would then be oriented on “upper” sides of the other elements. The exemplary term “lower”, can therefore, encompasses both an orientation of “lower” and “upper,” depending of the particular orientation of the Fig. Similarly, if the device in one of the Fig. s is turned over, elements described as “below” or “beneath” other elements would then be oriented “above” the other elements. The exemplary terms “below” or “beneath” can, therefore, encompass both an orientation of above and below.

It will be further understood that the terms “comprises” and/or “comprising”, or “includes” and/or “including”, or “has” and/or “having”, or “carry” and/or “carrying”, or “contain” and/or “containing”, or “involve” and/or “involving”, “characterized by”, and the like are to be open-ended, i.e., to mean including but not limited to. When used in this disclosure, they specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the invention, and will not be interpreted in an idealized or overly formal sense unless expressly so defined herein.

As used in the disclosure, “around”, “about”, “approximately” or “substantially” shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated.

As used in the disclosure, the phrase “at least one of A, B, and C” should be construed to mean a logical (A or B or C), using a non-exclusive logical OR. As used herein, the term “and/or” includes any and all combinations of one or more of the associated listed items.

The description below is merely illustrative in nature and is in no way intended to limit the invention, its application, or uses. The broad teachings of the invention can be implemented in a variety of forms. Therefore, while this invention includes particular examples, the true scope of the invention should not be so limited since other modifications will become apparent upon a study of the drawings, the specification, and the following claims. For purposes of clarity, the same reference numbers will be used in the drawings to identify similar elements. It should be understood that one or more steps within a method may be executed in different order (or concurrently) without altering the principles of the invention.

### Fully Connected Feed Forward Neural Networks (FFNNs) and Piecewise Linear Regression

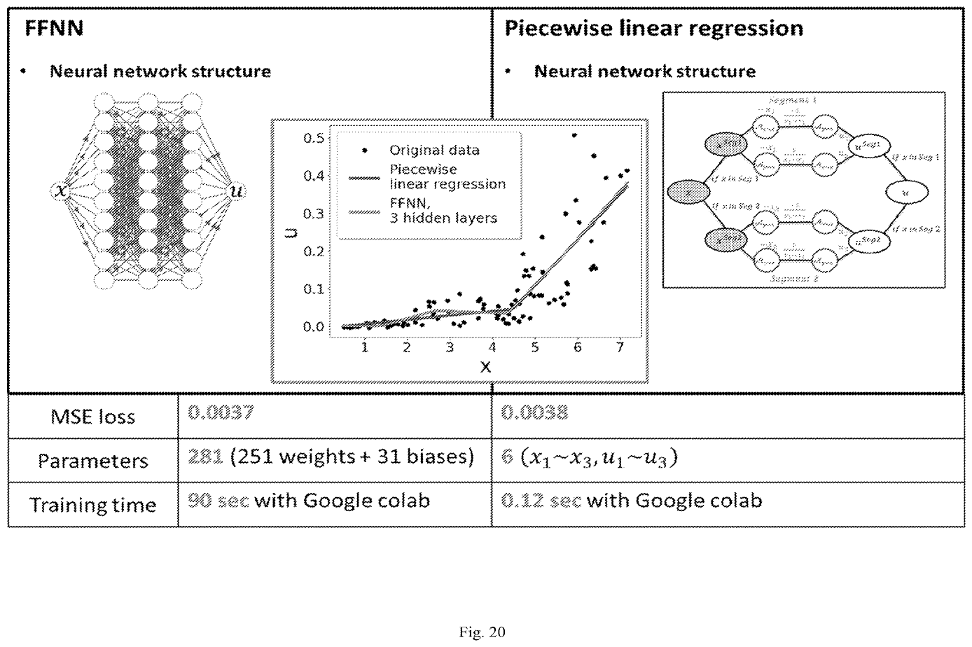

In one embodiment, we discuss the key motivation of the convolution hierarchical deep-learning neural network (C-HiDeNN) theory. Feed forward neural network (FFNN) is the most basic neural network structure for a regression problem, enabled by the universal approximation theory. That is, a deep enough FFNN can approximate any functional relationship if the neural network is well trained with a large number of datasets. However, a fully connected deep neural network necessitates a significant number of training parameters called weights and biases, limiting the efficiency of the program. One the other hand, it is possible to dramatically reduce the number of trainable parameters by predefining the shape of the approximation function. For example, by looking at the dataset plotted in FIG. 20, we can assume that the dataset follows a piecewise linear trend that consists of two linear regression lines. For the same dataset, an FFNN regression with 3 hidden layers and 10 neurons for each layer and a piecewise linear regression are conducted. As shown in FIG. 20, the mean squared error of the trained regressions are similar to each other, but the number of trainable parameters are 281 for the FFNN and only 6 for the piecewise linear regression, resulting in a huge reduction in the training time (computational cost) of the piecewise linear regression.

This example implies that we can dramatically improve the efficiency of a neural network by assuming the functional form of the neural network, which became the foundation of the C-HiDeNN theory.

### C-HiDeNN Theory and Algorithm

C-HiDeNN theory and algorithm is based on the Hierarchical Deep-learning Neural Network (HiDeNN)-FEM, which replaces the entire FEM process with partially connected hierarchical DNNs. HiDeNN-FEM shape functions replace the weights and biases with the nodal coordinates and the nodal field variables such that they are mathematically equivalent to FEM shape functions. Then the elementwise HiDeNN-FEM shape functions coalesce to form a global loss function based on the principle of minimum potential energy. Now the problem has changed from classical FEM to an optimization problem, which is the core concept of Engineering Software 2.0. Since both the nodal coordinates and the nodal field variables compose the HiDeNN-FEM shape functions, the present invention solves nodal field variables while updating (or training) nodal coordinates, x, (analogous to the r-mesh adaptivity) at the same time.

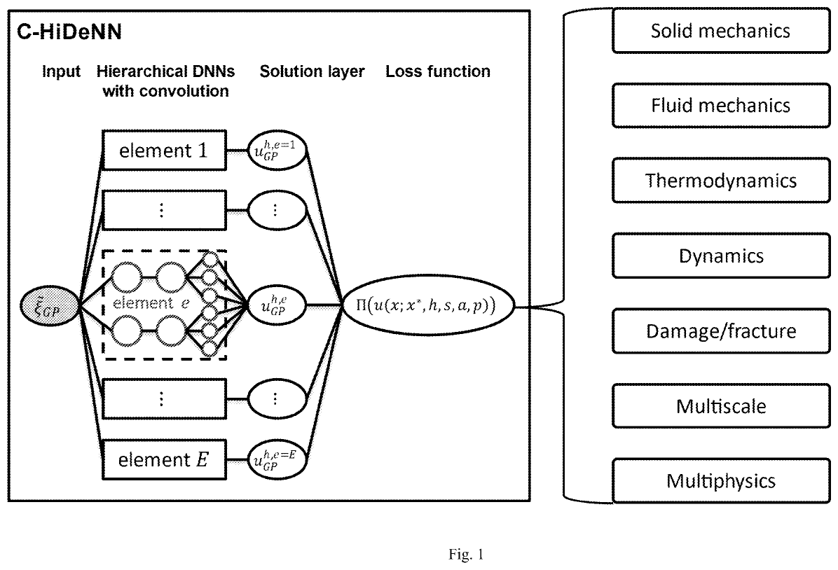

C-HiDeNN is the seamless integration of HiDeNN-FEM shape functions with convolution patch functions to expand the linear interpolation space to nonlinear or arbitrary functions, whose neural network structure is illustrated in FIG. 1. In terms of the functional space, C-HiDeNN encompasses HiDeNN-FEM because of these convolution patch functions. C-HiDeNN shape functions are built on the partition of unity (POU) concept, using the linear finite element family but can be designed to have higher smoothness and arbitrary “p” order of convergence rates; no need to exploit higher order elements. The resulting features of C-HiDeNN are orders of magnitude more accurate solutions, faster convergence rates, and the removal of locking with the linear finite element meshes. The convolution patch functions are constructed by interpolating “s”-layer of neighboring elements called patch domain. These patch functions are controlled by patch size “s”, dilation parameter “a”, and reproducing order “p”, which is analogous to adding/deleting extra hidden layers or neurons to a neural network. They behave like convolution filters that are used in signal processing, applied mathematics, convolutional neural networks, and the reproducing kernel particle method (RKPM).

Global DOFs of C-HiDeNN are the same as the linear FEM as they are still using linear elements, but the C-HiDeNN global stiffness matrix has a larger bandwidth than that of the linear FEM. For this reason, the iterative solver time of C-HiDeNN is longer than the FEM with the same degrees of freedom, but the slowdown is compensated by drastic improvements in accuracy and “p”-order convergence rates. The major computational overhead of C-HiDeNN comes from the addition of the convolution patch functions. In one embodiment, the present invention parallelizes this computation with graphics processing units (GPUs) programming algorithm.

C-HiDeNN theory and algorithm can be applied to various Computational Science and Engineering (CS&E) problems including but not limited to linear/nonlinear solid mechanics problems, damage/fracture problems, thermal and fluid problems, multiphysics and multiscale problems, and many more, as shown in FIG. 1.

### Hierarchical Deep-Learning Neural Networks (HiDeNN)-FEM

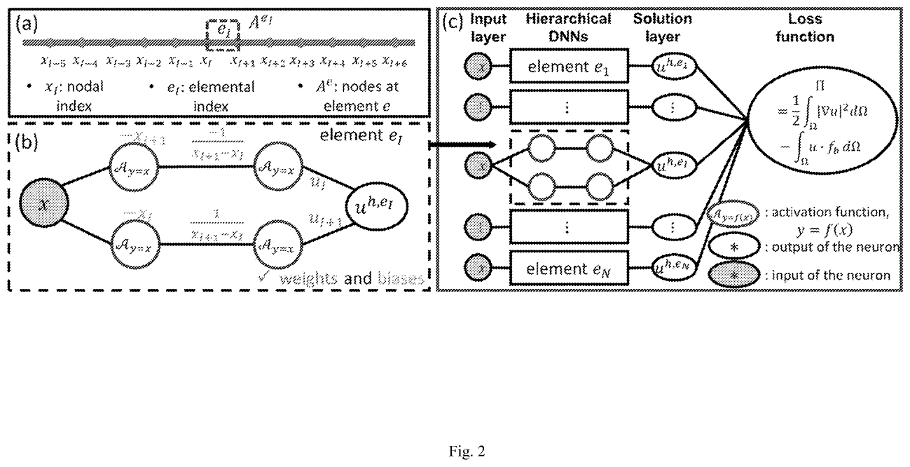

FIG. 2 shows HiDeNN-FEM formulation for a 1-D Poisson's problem. Light blue and orange terms are weights and biases of the neural network, respectively. If there is no weight or bias assigned for a neuron, it will have fixed weight=1 and bias=0. Functions inside neurons with blue edges represent activation functions while those with black edges represent the inputs (green color) and outputs (white color) of the neuron. Panel (a) shows nodal coordinates in physical space with an element of interest er. Panel (b) represents HiDeNN-FEM shape function of the element e_{I}. This small neural network constitutes the hierarchical DNN layer of the global neural network Panel (c).

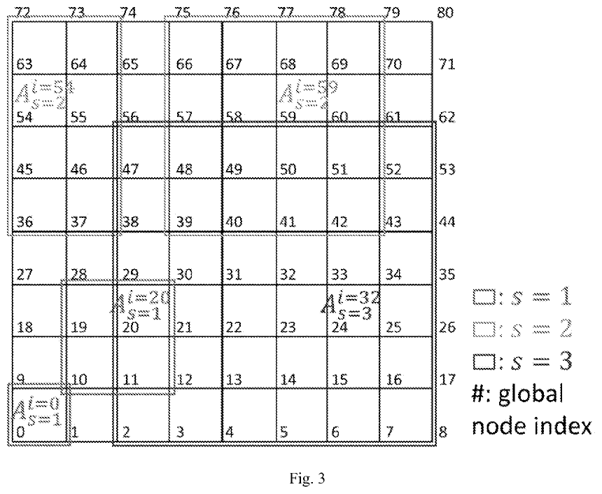

HiDeNN-FEM is a custom-designed neural network such that the mathematical form of the neural network can be equivalent to POU-FEM or POU-meshfree methods, and many others. As can be seen in FIG. 2 panel (b), the elementwise shape function is expressed with two hidden layers and two hidden neurons on each layer. This is written as

$${u}^{h , {e}_{I}} ( x ) = {𝒜}_{y = x} ( - \frac{1}{{x}_{I + 1} - {x}_{I}} {𝒜}_{y = x} ( x - {x}_{I + 1} ) ) {u}_{I} + {𝒜}_{y = x} ( \frac{1}{{x}_{I + 1} - {x}_{I}} {𝒜}_{y = x} ( x - {x}_{I} ) ) {u}_{I + 1} \qquad ( 1 )$$

where u^{h,e}^{_{I}}(x) is the approximated field variable at element e_{I}, u_{I} is the nodal field value, and [symbol] _{y=f(x)} represents an activation function of y=f(x). For example, [symbol] _{y=x} and [symbol] _{y=max (x,0)} represent the identity and Rectified Linear Unit (ReLU) activation functions, respectively. Thus, the activation functions are non-trainable once they are defined. Note that the hidden layers are partially connected, and the corresponding weights and biases are constrained to be functions of nodal coordinates and nodal field variables. HiDeNN-FEM can also be constructed for “p” finite elements such as higher order polynomial, B-spline, and reproducing kernel approximation. FIG. 3 illustrates the nodal patch domain

$$( {A}_{s}^{i} )$$

a 2-D, 8×8 element mesh. s is the patch size and the domains are colored by the patch size.

### Convolution Patch Functions

Convolution patch functions interpolate the nodal patch domain

$${A}_{s}^{i}$$

where s is the patch size (integer) and i is the center node.

$${A}_{s}^{i}$$

refers to a domain centered at node i and s layers of elements surrounding node i. Suppose that one has an 8×8 uniform element depicted in FIG. 3. By definition,

$${A}_{s = 1}^{i = 20}$$

refers to one layer of nodes surrounding node 20: nodes 10, 11, 12, 19, 20, 21, 28, 29, 30. The same applies to the other domains. Note that nodes near the domain boundary might have patch domains that are different in size and shape compared with those far from the boundary. For example,

$${A}_{s = 1}^{i = 0}$$

consists of four nodes as the center node 0 is at the corner of the global domain. Similarly,

$${A}_{s = 2}^{i = 54}$$

has only 15 nodes because the center node 54 is at the domain boundary. Although FIG. 3 only describes a uniform 2-D mesh, the same rule works for non-uniform 3-D meshes. In one embodiment, nodal coordinates of a patch domain

$${A}_{s}^{i}$$

are denoted as

$${x}^{{A}_{s}^{i}} .$$

One way of constructing convolution patch functions is by borrowing well-established meshfree techniques. One can use the reproducing kernel element method (RKEM), hierarchical enrichment, radial point interpolation method, reproducing kernel peridynamics, etc. In one embodiment, the present invention borrows the idea of the radial point interpolation method (RPIM) as it achieves stable interpolants possessing a Kronecker delta property. Although the RPIM theory is grounded in the meshfree method, one will call this interpolation function the convolution patch function in the rest of this work for consistency of notation and generality.

In the present invention, the RPIM theory is reviewed. A field variable u(x) inside a nodal patch domain

$${A}_{s}^{i}$$

can be interpolated with radial basis Rⱼ(x) and polynomial basis pₖ(x) functions as

$$u ( x ) = {\sum }_{j = 1}^{n} {R}_{j} ( x ) {b}_{j} + {\sum }_{k = 1}^{m} {p}_{k} ( x ) {c}_{k} = {R}^{T} ( x ) b + {p}^{T} ( x ) c = [ \begin{matrix}{R}^{T} ( x ) & {p}^{T} ( x )\end{matrix} ] \{ \begin{matrix}b \\ c\end{matrix} \} \qquad ( 2 )$$

where n is the number of nodes in a domain

$${A}_{s}^{i}$$

and m is the number of complete polynomial basis functions, which is determined by the reproducing polynomial order p and the dimension of the problem. For example, in a 2-D problem, second order reproducing condition (p=2) requires m=6 polynomial basis functions: 1, x, y, x², xy, y² b and c are the coefficients to be determined by imposing the Kronecker delta function property.

A radial basis function Rⱼ(x) is a function of only the radial distance between x and xⱼ (=rⱼ(x)). For 2-D problems with Euclidean norm, Rⱼ(x) is a function of

rⱼ(x)=\sqrt{(x−xⱼ)²+(y−yⱼ)²} (3)

where (xⱼ, yⱼ) is the coordinate of node j. One can use compactly supported radial basis functions listed in Table 1 where one chooses the cubic spline function for our program. In these functions, the dimension of local support is determined by the dilation parameter a. If

$$\frac{{r}_{j}}{a} > 1 ,$$

the radial basis functions return zero.

TABLE 1
Typical compactly supported radial basis functions.

| Function | Formulation | Reference |
|---|---|---|
| Cubic spline | ${R}_{j} ( {r}_{j} ; a ) = \{ \begin{matrix}\frac{2}{3} - 4 \frac{{r}_{j}^{2}}{{a}^{2}} + 4 \frac{{r}_{j}^{3}}{{a}^{3}} & for 0 \leq \frac{{r}_{j}}{a} \leq \frac{1}{2} \\ \frac{4}{3} - 4 \frac{{r}_{j}}{a} + 4 \frac{{r}_{j}^{2}}{{a}^{2}} - \frac{4}{3} \frac{{r}_{j}^{3}}{{a}^{3}} & for \frac{1}{2} \leq \frac{{r}_{j}}{a} \leq 1 \\ 0 & otherwise\end{matrix}$ | Liu (1995) |
| Wu-C2 | ${R}_{j} ( {r}_{j} ; a ) = \{ \begin{matrix}{( 1 - \frac{{r}_{j}}{a} )}^{5} ( 8 + 40 \frac{{r}_{j}}{a} + 48 \frac{{r}_{j}^{2}}{{a}^{2}} + 25 \frac{{r}_{j}^{3}}{{a}^{3}} + 5 \frac{{r}_{j}^{4}}{{a}^{4}} ) & for 0 \leq \frac{{r}_{j}}{a} \leq 1 \\ 0 & otherwise\end{matrix}$ | Wu (1995) |
| Wendland-C2 | ${R}_{j} ( {r}_{j} ; a ) = \{ \begin{matrix}{( 1 - \frac{{r}_{j}}{a} )}^{4} ( 1 + 4 \frac{{r}_{j}}{a} ) & for 0 \leq \frac{{r}_{j}}{a} \leq 1 \\ 0 & otherwise\end{matrix}$ | Wendland (1995) |

The coefficients bⱼ and cₖ are determined by imposing the Kronecker delta function property, which can be written as

uₙ=Rₙb+PₘC (4)
where the vector for the nodal field variable is

uₙ={u₁,u₂, . . . uₙ}^{T}, (5)
the moment matrix of the radial basis function is

$${R}_{n} = {[ \begin{matrix}{R}_{1} ( {r}_{1} ) & {R}_{2} ( {r}_{1} ) & … & {R}_{n} ( {r}_{1} ) \\ {R}_{1} ( {r}_{2} ) & {R}_{2} ( {r}_{2} ) & … & {R}_{n} ( {r}_{2} ) \\ ⋮ & ⋮ & ⋱ & ⋮ \\ {R}_{1} ( {r}_{n} ) & {R}_{2} ( {r}_{n} ) & … & {R}_{n} ( {r}_{n} )\end{matrix} ]}_{( n \times n )} , \qquad ( 6 )$$

the moment matrix of the polynomial basis function is

$${P}_{m} = {[ \begin{matrix}1 & {x}_{1} & {y}_{1} & … & {p}_{m} ( {x}_{1} ) \\ 1 & {x}_{2} & {y}_{2} & … & {p}_{m} ( {x}_{2} ) \\ ⋮ & ⋮ & ⋮ & ⋱ & ⋮ \\ 1 & {x}_{n} & {y}_{n} & … & {p}_{m} ( {x}_{n} )\end{matrix} ]}_{( n \times m )} , \qquad ( 7 )$$

and the coefficients b and c are

b={b₁b₂ . . . bₙ}^{T}

c={c₁c₂ . . . cₘ}^{T}. (8)

As seen in Eq. (8), one has total (n+m) unknowns but there are only n equations in Eq. (4). Therefore, one needs extra m equations to fully determine the coefficients. The following additional m constraints are usually used to resolve the ambiguity:

$${P}_{m}^{T} b = 0 . \qquad ( 9 )$$

Finally, one gets the system of (n+m) linear equations:

$$\{ \begin{matrix}{u}_{n} \\ 0\end{matrix} \} = [ \begin{matrix}{R}_{n} & {P}_{m} \\ {P}_{m}^{T} & 0\end{matrix} ] \{ \begin{matrix}b \\ c\end{matrix} \} = G \{ \begin{matrix}b \\ c\end{matrix} \} . \qquad ( 10 )$$

Note that the assembled moment matrix G is symmetric because the radial basis moment matrix Rₙ is also symmetric and the additional m constraints are set as the transpose of Pₘ (see Eq. (9)). If G is a full-rank matrix, the coefficients b and c are uniquely determined as

$$\{ \begin{matrix}b \\ c\end{matrix} \} = {G}^{- 1} \{ \begin{matrix}{u}_{n} \\ 0\end{matrix} \} . \qquad ( 11 )$$

By substituting Eq. (2) with Eq. (11), one gets

$$u ( x ) = [ \begin{matrix}{R}^{T} ( x ) & {p}^{T} ( x )\end{matrix} ] {G}^{- 1} \{ \begin{matrix}{u}_{n} \\ 0\end{matrix} \} = \tilde{W} ( x ) \{ \begin{matrix}{u}_{n} \\ 0\end{matrix} \} . \qquad ( 12 )$$

In one embodiment, \tilde{W}(x) is a (n+m)-component row vector and the last m components are ignored because they are multiplied by zeros. If one denotes the first n components of \tilde{W}(x) by \tilde{W}(x), which one refers to as convolution patch functions, one finally can interpolate the field variable using radial basis functions with reproducing polynomial order p and the Kronecker delta property:

u(x)=W(x)uₙ (13)

Likewise, the derivative of the convolution patch function can be obtained by replacing the basis functions with their derivatives:

$$\frac{\partial u ( x )}{\partial x} = [ \begin{matrix}\frac{\partial {R}^{T} ( x )}{\partial x} & \frac{\partial {p}^{T} ( x )}{\partial x}\end{matrix} ] {G}^{- 1} \{ \begin{matrix}{u}_{n} \\ 0\end{matrix} \} = \frac{\partial \tilde{W} ( x )}{\partial x} \{ \begin{matrix}{u}_{n} \\ 0\end{matrix} \} . \qquad ( 14 )$$

Since one can arbitrarily choose reproducing order p, C-HiDeNN can achieve arbitrary convergence rates, resulting in superior accuracy compared to linear FEM. In addition, due to the Kronecker delta function property, one does not need special treatment for boundary conditions.

### Graph Theory for Computing Nodal Connectivity

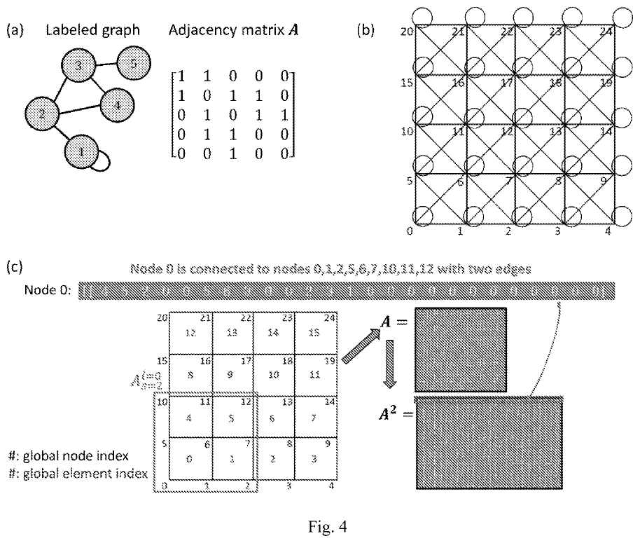

FIG. 4 shows in panel (a) A basic illustration of graph theory; panel (b) A graph for 4×4 uniform element. For each element, all pairs of nodes are connected, including self-connection; and panel (c) shows how the graph theory is used to find nodal patch domain

$${A}_{s}^{i} .$$

The nodal patch domain

$${A}_{s}^{i}$$

is a domain centered at node i and encompasses s layers of elements surrounding node i. This definition naturally embodies the concept of nodal (or elemental) connectivity, for which, in one embodiment, the present invention borrows ideas from graph theory. In this section, one reviews the basic graph theory and demonstrates how it finds patch domains efficiently.

Graphs in graph theory refer to mathematical structures that display pairwise connectivity relationships between nodes. FIG. 4 panel (a) shows a labeled graph of five nodes (aka vertices) and their connectivity relationships displayed with edges. For example, node two is connected to nodes 1, 3, and 4, while node 1 is connected to node 1 (itself) and 2. The graph is mathematically represented with a binary 5×5 matrix, called the adjacency matrix A, whose components are defined as:

$${A}_{ij} = \{ \begin{matrix}1 , & if node i and node j are connected \\ 0 , & if node i and node j are not connected\end{matrix} \qquad ( 15 )$$

In graph theory, the s^{th} power of the adjacency matrix A^{s} represents s^{th} order connectivity. That is,

$${A}_{i j}^{s}$$

is the number of different ways to move from node i to node j that pass through s edges (i.e., in s steps).

In FIG. 4 panel (b), one generates an adjacency matrix based on a 4×4 elements (or 5×5 nodes) uniform mesh. It is assumed that all nodes in an element are connected, and each node has a self-connection. For example, node 0 is connected to node 0 (itself), 1, 5, and 6. Node 1 is connected to nodes 0, 1 (itself), 2, 5, 6, and 7. The generated adjacency matrix is a 25×25 sparse, binary, square, and symmetric matrix.

By definition, A² tells us the second-order connectivity. The red dashed box in FIG. 4 panel (c) shows the first row of A² where one can see components 0, 1, 2, 5, 6, 7, 10, 11, and 12 are non-zero. This means that these nodes are connected to node 0 with two edges, and the value of each component tells the number of different combinations of two edges. The nodal patch domain at node i=0 with patch size s=2 is therefore

$${A}_{s = 2}^{i = 0} = \{ 0 , 1 , 2 , 5 , 6 , 7 , 10 , 11 , 12 \} . \qquad ( 16 )$$

Likewise, one can readily get other patch domains from the same matrix A².

$${A}_{s = 2}^{i = 6} = \{ 0 , 1 , 2 , 3 , 5 , 6 , 7 , 8 , 10 , 11 , 12 , 13 , 15 , 16 , 17 , 18 \} \qquad ( 17 )$$

$${A}_{s = 2}^{i = 12} \{ 0 , 1 , 2 , 3 , 4 , 5 , 6 , 7 , 8 , 9 , 10 , 11 , \\ 12 , 13 , 14 , 15 , 16 , 17 , 18 , 19 , 20 , 21 , 22 , 23 , 24 \}$$

$$…$$

$${A}_{s = 2}^{i} = \{ j \vert j is a non - zero column index of {i}^{th} row of {A}^{2} \}$$

One important reason for using graph theory is that the adjacency matrix is a sparse binary matrix. Thus, one can use sparse matrix libraries for matrix multiplication that can save a huge amount of memory and computation time. In our current code, one use SciPy1 at scipy.org sparse matrix libraries in Python to compute nodal patch domains with no need for parallelization, as it is fast enough with the serial SciPy algorithm (for one million nodes, A² and A⁴ took 4 and 6 seconds, respectively).

### C-HiDeNN Formulation for 1-D Poisson's Problem

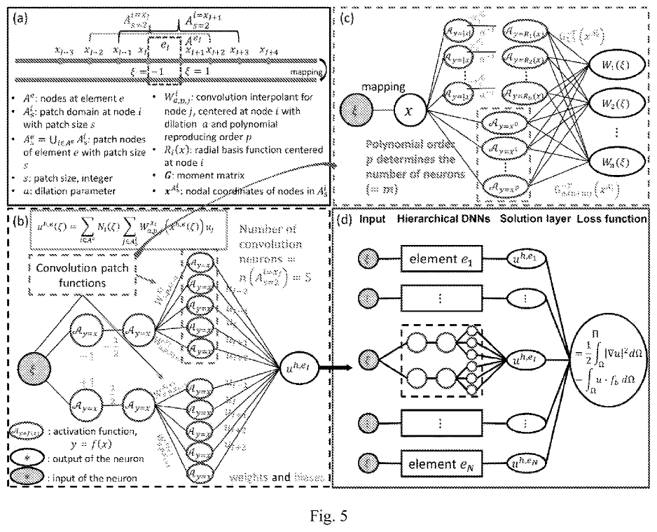

FIG. 5 shows C-HiDeNN formulation for a 1-D Poisson's problem. Light blue and orange terms are weights and biases of the neural network, respectively. If there is no weight or bias assigned for a neuron, it will have fixed weight=1 and bias=0. Functions inside neurons with blue edges represent activation functions while those with black edges represent the input (green color) and output (white color) of the neuron. Panel (a) shows nodal coordinates in both physical and parametric space, focusing on the element of interest e_I. Nodal patch domains and other terminologies are defined below. Panel (b) represents the C-HiDeNN shape function of the element e_I, which constitutes the hierarchical DNN layer of the global neural network (d). Panel (c) is the convolution patch function that can be found in the brown dashed box in panel (b).

This section demonstrates how, in one embodiment, the present invention formulates C-HiDeNN. For simplicity, one starts with a 1-D Poisson's equation but later expands to 2-D and 3-D problems. The interpolated field variable in element e in the parametric domain (u^{h,e}(ξ)) is given as:

$${u}^{h , e} ( ξ ) = {\sum }_{i ∈ {A}^{e}} {N}_{i} ( ξ ) {\sum }_{j ∈ {A}_{s}^{i}} {W}_{a , p , j}^{{x}_{i}} ( {x}^{h , e} ( ξ ) ) {u}_{j} = {\sum }_{k ∈ {A}_{s}^{e}} {\tilde{N}}_{k} ( ξ ) {u}_{k} , \qquad ( 18 )$$

with elementwise mapping from the parametric domain to the physical domain for element e:

$${x}^{h , e} ( ξ ) = {\sum }_{i ∈ {A}^{e}} {N}_{i} ( ξ ) {x}_{i} \qquad ( 19 )$$

where Nᵢ(ξ) is a general polynomial interpolant (for simplicity, one can view this as linear FEM shape functions) as node i and

$${W}_{a , p , j}^{{x}_{i}} ( {x}^{h , e} ( ξ ) )$$

is the convolutional patch function at node j defined on the support domain

$${A}_{s}^{i} .$$

It is important to note that the convolution patch function is defined in the physical domain with x-coordinates because it is more straightforward to implement the RPIM theory. If one wants to define the convolution patch function in the parametric domain with ξ-coordinates, an inverse mapping from the physical domain to the parametric domain is required, which is mathematically nonobvious. Therefore, one first maps from ξ-coordinates to x-coordinates using Eq. (19), then compute convolution patch function in the physical domain.

Finally, the double summation is rearranged to a single summation over elemental patch nodes

$${A}_{s}^{e} = {⋃}_{i ∈ {A}^{e}} {A}_{s}^{i} .$$

In one embodiment, one highlights the definition of elemental patch nodes

$${A}_{s}^{e} .$$

The element er in FIG. 5 panel (a) has two nodal patch domains,

$${A}_{s = 2}^{i = {x}_{I}} = \{ {x}_{I - 2} , … {x}_{I + 2} \}$$

$$and$$

$${A}_{s = 2}^{i = {x}_{I + 1}} = \{ {x}_{I - 1} , … {x}_{I + 3} \}$$

when s=2. As the elemental patch domain is the union of nodal patch domains,

$${A}_{s = 2}^{e = {e}_{I}} = \{ {x}_{I - 2} , … {x}_{I + 3} \} .$$

Now the interpolated field variable u^{h,e}(ξ) is expressed as a summation of the convolutional interpolant Ñₖ(ξ) times nodal variable uₖ over the elemental patch nodes

$${A}_{s}^{e}$$

(Eq. (18)). Definitions of the notation can also be found in FIG. 5 panel (a).

The general polynomial interpolant Nᵢ(ξ) satisfies compact support and partition of unity, while the convolutional patch function

$${W}_{a , p , j}^{{x}_{i}} ( ξ )$$

additionally satisfies the Kronecker delta and reproducing conditions. These conditions are given:

$$\begin{matrix}\begin{matrix}Compact support for \\ general polynomial interpolants\end{matrix} & {A}^{e} ⊂ {⋃}_{i ∈ {A}^{e}} {A}_{s}^{i}\end{matrix} \qquad ( 20 )$$

$$\begin{matrix}Partition of unity for \\ general polynomial interpolants\end{matrix} \qquad {\sum }_{i ∈ {A}^{e}} {N}_{i} ( ξ ) = 1$$

$$\begin{matrix}\begin{matrix}Kronecker delta for \\ convolution patch functions\end{matrix} & {W}_{a , p , j}^{{x}_{i}} ( x ) {\vert}_{x = {x}_{l}}\end{matrix} = {δ}_{jl} , where j , l ∈ {A}_{s}^{i}$$

$$\begin{matrix}Reproducing condition for \\ convolution patch functions\end{matrix} \qquad {\sum }_{j ∈ {A}_{s}^{i}} {W}_{a , p , j}^{{x}_{i}} ( x ) p ( {x}_{j} ) = p ( x )$$

The resulting convolution interpolant Ñₖ(ξ) satisfies the partition of unity, Kronecker delta, and reproducing conditions, thus the application of both Dirichlet and Neumann boundary conditions is straightforward.

The neural network formulation of C-HiDeNN is visualized in FIG. 5 such that it follows a similar format to HiDeNN-FEM in FIG. 2. FIG. 5 panel (a) illustrates how the nodal patch domains

$${A}_{s}^{i}$$

are constructed based on the patch size s. FIG. 5 panel (b) shows an elemental shape function like the one in FIG. 2 panel (b). The first two hidden layers with two hidden neurons are the same as HiDeNN-FEM. However, C-HiDeNN has one more hidden layer with a greater number of neurons that represent enhanced connectivity between neighboring nodes. Note that the number of neurons on the third hidden layer is determined by the number of elements of the nodal patch domain,

$$n ( {A}_{s}^{i} )$$

(see the purple dashed box in FIG. 5 panel (b)). Like Eq. (1), one can write this elemental neural network as:

$${u}^{h , {e}_{I}} ( ξ ) = {\sum }_{j ∈ {A}_{s}^{I}} [ {u}_{j} {𝒜}_{y = x} ( {W}_{a , p , j}^{{x}_{I}} ( ξ ) {𝒜}_{y = x} ( - \frac{1}{2} {𝒜}_{y = x} ( ξ - 1 ) ) ) ] + {\sum }_{j ∈ {A}_{s}^{I + 1}} [ {u}_{j} {𝒜}_{y = x} ( {W}_{a , p , j}^{{x}_{I + 1}} ( ξ ) {𝒜}_{y = x} ( \frac{1}{2} {𝒜}_{y = x} ( ξ + 1 ) ) ) ] . \qquad ( 21 )$$

The weights of the third hidden layer are the convolution patch functions constructed by a sub-neural network in FIG. 5 panel (c). This follows the derivation of RPIM. One can also write this sub-neural network as:

$${W}_{j} ( ξ ) = {\sum }_{l = 1}^{n} [ {G}_{j , l}^{- T} {𝒜}_{y = {R}_{l} ( x )} ( \frac{1}{a} {𝒜}_{y = \vert x \vert} ( x ( ξ ) - {x}_{l}^{{A}_{s}^{i}} ) ) ] + {\sum }_{k = 1}^{m} [ {G}_{j , n + k}^{- T} {𝒜}_{y = {x}^{k - 1}} ( x ( ξ ) ) ] \qquad ( 22 )$$

$$j = 1 , 2 , ⋯ , n$$

where the mapping from the parametric domain to the physical domain is

x(ξ)=Σ_{i∈A}_{^{e}}Nᵢ(ξ)xᵢ, (23)
n is the number of nodes in a patch domain

$${A}_{s}^{I} ,$$

and the assembled moment matrix G is taken from Eq. (10). The

$${G}_{j , l}^{- T}$$

is (j, l) component of the inverse transpose of G. It is important to note that the reproducing polynomial order p determines the number of neurons inside the red dashed box (=m) in FIG. 5 panel (c). In 1-D, there are m=p+1 neurons, each of which represents polynomial basis from x⁰ to x^{p}.

The first hidden layer in FIG. 5 panel (c) normalizes the radial distance by passing it through the absolute activation function [symbol] _{y=|x|} and dividing it with the dilation parameter a. Then the normalized distance enters the second hidden layer with the radial basis activation function. In one embodiment, the dilation parameter a extracts multiresolution features of a patch domain by acting as a normalization parameter of radial distances and turning off neurons in the second hidden layer whose normalized radial distance is farther than a. The first and second hidden layers correspond to the radial and polynomial basis functions [R^{T}(x) p^{T}(x)] in Eq. (12). Between the second hidden layer and the output layer, the inverse of the assembled moment matrix G⁻¹ is multiplied component-wise. This operation corresponds to [R^{T}(x) p^{T}(x)] G⁻¹ in Eq. (12). Thus, the output layer of FIG. 5 panel (c) yields convolution patch functions W(x).

Finally, the elementwise neural network in FIG. 5 panel (b) and Eq. (22) is integrated with the sub-neural network for the convolution patch functions in FIG. 5 panel (c) and Eq. (23), yielding:

$${u}^{h , {e}_{I}} ( ξ ) = {\sum }_{j ∈ {Λ}_{s}^{I}} [ {u}_{j} {𝒜}_{y = x} ( \{ {\sum }_{j ∈ {Λ}_{s}^{I}} [ {G}_{j , l}^{- T} {𝒜}_{y = {R}_{l} ( x )} ( \frac{1}{a} {𝒜}_{y = \vert x \vert} ( x ( ξ ) - {x}_{l}^{{A}_{s}^{i}} ) ) ] + {\sum }_{k = 1}^{m} [ {G}_{j , n + k}^{- T} {𝒜}_{y = {x}^{k - 1}} ( x ( ξ ) ) ] \} {𝒜}_{y = x} ( - \frac{1}{2} {𝒜}_{y = x} ( ξ - 1 ) ) ) ] + {\sum }_{j ∈ {A}_{s}^{I + 1}} [ {u}_{j} {𝒜}_{y = x} ( \{ {\sum }_{j ∈ {A}_{s}^{I + 1}} [ {G}_{j , l}^{- T} {𝒜}_{y = {R}_{l} ( x )} ( \frac{1}{a} {𝒜}_{y = \vert x \vert} ( x ( ξ ) - {x}_{l}^{{A}_{s}^{i}} ) ) ] + {\sum }_{k = 1}^{m} [ {G}_{j , n + k}^{- T} {𝒜}_{y = {x}^{k - 1}} ( x ( ξ ) ) ] \} {𝒜}_{y = x} ( ξ + 1 ) ) ) ] . \qquad ( 24 )$$

Eq. (24) is a neural network representation of elemental C-HiDeNN interpolants in 1-D that corresponds to Eq. (18). Like HiDeNN-FEM in FIG. 2, these elementwise neural networks compose the global neural network in FIG. 5 panel (d).

One can see the “hierarchy” among the neural networks: the global neural network in FIG. 5 panel (d), the elemental neural network in FIG. 5 panel (b), and the sub-neural network for convolution patch functions in FIG. 5 panel (c). One can then formulate optimization problems as below:
Solve (find nodal solutions):

$$U = arg {min}_{{u}_{i} ∈ {ℝ}^{d}} \prod ( {u}^{C - HiDeNN} ( x ; U , X , a , s , p ) )$$

Train (find optimal parameters):

$$X , a , s , p = {arg min}_{{x}_{i} ∈ Ω \backslash \partial Ω , a ∈ {ℝ}^{+} , s ∈ ℕ , p ∈ ℕ} \prod ( {u}^{C - HiDeNN} ( x ; U , X , a , s , p ) )$$

where X is the nodal coordinates, U is the nodal variables, and s, a, and p are the convolutional interpolation parameters described above. Π is the loss function to be minimized formulated for the given computational science and engineering (CS&E) problem, which in this case, is the Poisson's equation. The first optimization solves for the nodal variables, given the nodal coordinates and the three parameters, s, a, and p. This is similar to the classical numerical methods. The second optimization trains the parameters, X, a, s, p, given the nodal solution U. The parameters s, a, p can be locally or globally optimized, rendering further improvements on the efficiency. This process is similar to the mesh adaptivity in classical FEA, but C-HiDeNN realizes versatile adaptable parameters with a more systematical approach by leveraging hierarchical neural networks. In summary, C-HiDeNN can both solve and train for a given partical differential equation (PDE) that is much more accurate and faster than classical numerical methods.

### C-HiDeNN Formulation for 2-D and 3-D Problems

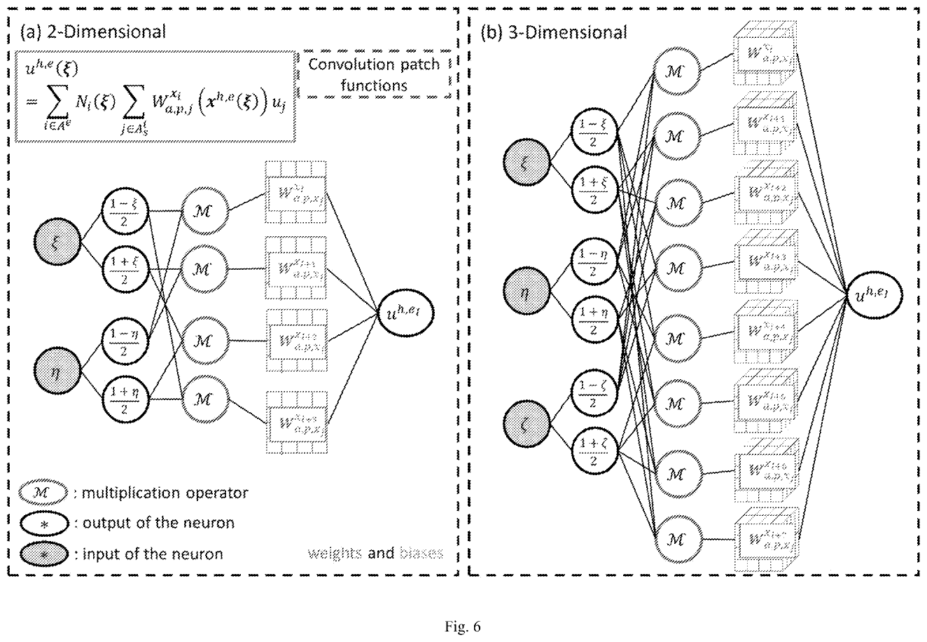

The C-HiDeNN structure can readily be expanded to n-dimensional problems by employing n-dimensional kernels as convolution patch functions. FIG. 6 illustrates C-HiDeNN shape functions for 2-D 4-node element (a) and 3-D 8-node element (b) each of which corresponds to FIG. 5 panel (b), the black dashed box. The first hidden layer outputs unidirectional shape functions followed by the multiplication building blocks (red-edged neurons) in the second hidden layer, but in short, it is a neuron that performs multiplication operations). Thus, the output of the second hidden layer is the nodal finite element shape function in the parametric domain. Then the third hidden layer is responsible for the convolution operation with 2-D (a), or 3-D (b) kernels whose values are from the convolution patch functions. Like the 1-D example in FIG. 5 panel (b), the patch size s determines the size of the kernel while the kernel values are computed in the same way described in FIG. 5 panel (c).

FIG. 6 shows C-HiDeNN shape function of element e_{I} for 2-D 4-node (a) and 3-D 8-node (b) elements. Each figure is a replacement for FIG. 5 panel (b). A red-edged neuron with M symbol denotes a multiplication operator (i.e., multiply all inputs).

Conditions for Parameters “s”, “a”, and “p”

There are three controlling parameters in C-HiDeNN interpolation: s, a, p, which can be optimized to enhance solution efficiency for a specific problem. Table 2 summarizes conditions for those parameters. The patch size s is a positive integer and should be greater than or equal to p/2. If

$$s = \frac{p}{2} ,$$

the convolution patch function becomes the Lagrange polynomial regardless of the choice of radial basis functions. The dilation parameter a should be a positive real number [symbol] ⁺. The reproducing polynomial order p should be a positive integer.

TABLE 2
Conditions for parameters “s”, “a”, and “p”

| Parameters | s | a | p |
|---|---|---|---|
| Conditions | $s \geq \frac{p}{2} , s ∈ {ℕ}^{+}$ | a ∈ [symbol] ⁺ | p ∈ [symbol] ⁺ |

Solving C-HiDeNN within the FEM Framework

Although C-HiDeNN is represented as a neural network, one can formulate C-HiDeNN using the standard FEM framework. It is assumed the nodal coordinates are fixed and one only solve for nodal variables. Minimizing the potential energy with respect to nodal variables is equivalent to solving a variational form. As one can directly leverage the standard FEM formulation with the variational form, C-HiDeNN will be programmed under the FEM framework.

The present invention revisits the 1-D C-HiDeNN interpolation in Eq. (18):

$${u}^{h , e} ( ξ ) = {\sum }_{i ∈ {A}^{e}} {N}_{i} ( ξ ) {\sum }_{j ∈ {A}_{s}^{i}} {W}_{a , p , j}^{{x}_{i}} ( {x}^{h , e} ( ξ ) ) {u}_{j} = {\sum }_{k ∈ {A}_{s}^{e}} {\tilde{N}}_{k} ( ξ ) {u}_{k} . \qquad ( 25 )$$

In one embodiment, the finite element shape function Nᵢ(ξ) is in the parametric domain but the convolution patch function

$${W}_{a , p , j}^{{x}_{i}} ( {x}^{h , e} ( ξ ) )$$

is directly obtained in the physical domain. Therefore, the derivative of the variable is given as:

$$\frac{{du}^{h , e}}{dx} = {\sum }_{i ∈ {A}^{e}} \frac{{dN}_{i}}{dx} {\sum }_{j ∈ {A}_{s}^{i}} {W}_{a , p , j}^{{x}_{i}} {u}_{j} + {\sum }_{i ∈ {A}^{e}} {N}_{i} {\sum }_{j ∈ {A}_{s}^{i}} \frac{{dW}_{a , p , j}^{{x}_{i}}}{dx} {u}_{j} = {\sum }_{k ∈ {A}_{s}^{e}} \frac{d {\tilde{N}}_{k}}{dx} {u}_{k} , \qquad ( 26 )$$

The shape function derivative,

$$\frac{{dN}_{i}}{dx}$$

is obtained from the Jacobian transformation in standard FEM, while the derivative of the convolution patch function

$$\frac{{dW}_{a , p , j}^{{x}_{i}}}{dx}$$

is computed from Eq. (14). The resulting derivative of the convolution interpolant

$$\frac{d {\tilde{N}}_{k}}{dx}$$

is regarded as a shape function derivative of C-HiDeNN and the rest of the programming follows the standard FEM procedure (i.e., elemental stiffness matrix, numerical integration, global assembly, iterative solver, etc.)

One should be aware that each element of C-HiDeNN has more supporting nodes than FEM. The number of supporting nodes of C-HiDeNN is the number of elemental patch nodes:

$$n ( {A}_{s}^{e} ) .$$

Therefore, the size of the elemental stiffness matrix in C-HiDeNN for a 1-D field variable is

$$n ( {A}_{s}^{e} ) \times n ( {A}_{s}^{e} )$$

while that of FEM is n(A^{e})×n(A^{e}) the patch size

$$s = 2 ( n ( {A}_{s}^{e} ) = 6 ) ,$$

the size of the elemental stiffness matrix of C-HiDeNN and FEM are 6×6 and 2×2, respectively. Likewise, the nodal connectivity A^{e} should be replaced with the patch information

$${A}_{s}^{e}$$

when assembling the global stiffness matrix. One last thing to note is the Gauss integration. As the convolution patch functions are highly nonlinear, more integration points are needed than in linear FEM. In one embodiment, the present invention found six-point Gauss quadrature rule (in 1-D) is sufficient. Therefore, in 2-D and 3-D, one needs 36 and 216 integration points, respectively.

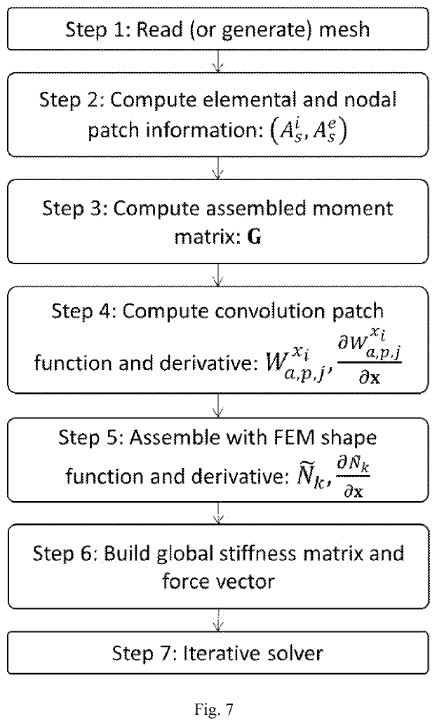

FIG. 7 shows the flowchart of C-HiDeNN for solving a Poisson's equation. The first step and the last two steps are similar to the standard FEM procedure. The boxes in between are C-HiDeNN-specific operations. In step 2, one can use graph theory to efficiently obtain patch information and nodal connectivity. Then one moves on to the next two steps (steps 3 and 4) for computing convolution patch functions according to the radial point interpolation theory. First, the assembled moment matrix G is measured at every element and every node in that element. Then the convolution patch functions

$${W}_{a , p , j}^{{x}_{i}} ( ξ )$$

are computed at every element, every node in the element, and every integration point. In step 5, according to Eq. (25) and (26), they are integrated with FEM shape functions to generate convolution interpolants

$${\tilde{N}}_{k} , \frac{d {\tilde{N}}_{k}}{dx} .$$

To build the global stiffness matrix at Step 6, the elemental patch nodes

$${A}_{s}^{e}$$

are used to connect between elemental and global degrees of freedom. Finally, in step 7, a Jacobi-preconditioned conjugate gradient iterative solver is used. GPU implementation of the iterative solver will be discussed in the next section.
GPU Acceleration with JAX Library

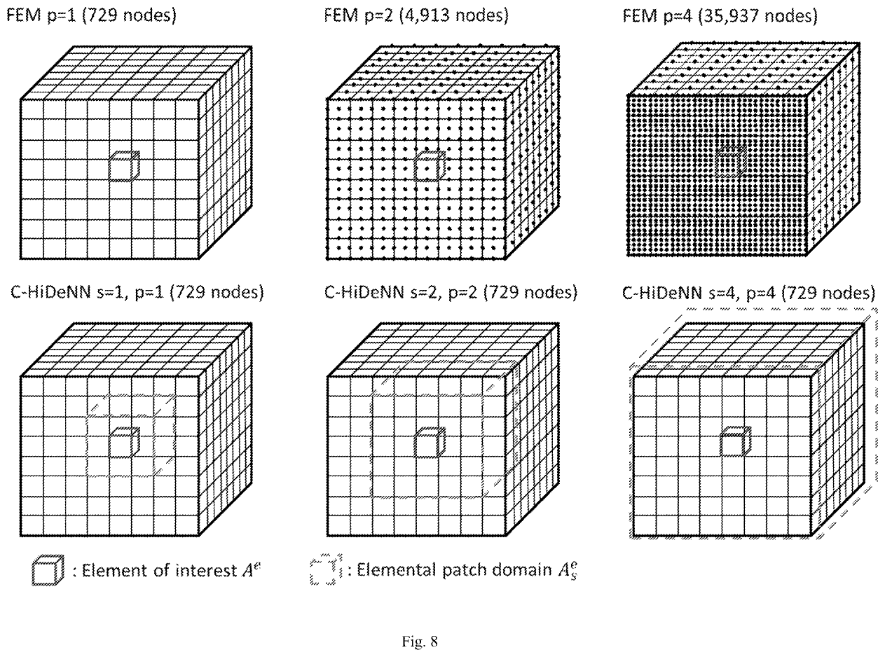

The major computational overhead of C-HiDeNN comes from building the convolution patch functions (steps 3 to 5 in FIG. 8). Based on the radial point interpolation theory, the convolution patch functions should be constructed at every element, every node in the element, and every numerical integration point. For example, if there are 100 elements, 4 nodes per element, and 36 integration points, 14,400 different convolution patch functions should be constructed, which is a huge amount of additional computation compared to FEM.

Fortunately, the computation of convolution patch functions is highly parallelizable. Constructing a patch function for one element is independent of the patch functions of the other elements. For this reason, parallel computation has a huge potential of reducing the computation time for building patch functions. In one embodiment, the present invention built the Python code using JAX1 at github.com/google/jax library that runs on both CPU and GPU.

JAX is a high-level Python library developed by Google that runs on CPU, GPU, and TPU (tensor processing unit). In terms of writing code, JAX is very similar to the NumPy2 at numpy.org library in Python. Due to the accelerated linear algebra (XLA) backend, JAX can be as fast as C/C++ programs and even faster when GPU or TPU is used. Compared to CUDA language, JAX is much easier to learn and use, but as fast as low-level programming languages. In FIG. 8, steps 3-5 are parallelized with the JAX “vmap” function. The usage is very simple. First, in one embodiment, the present invention defines a function that returns a single output, i.e.,

G=compute_moment_matrix(x). (27)

If it were a serial code, to compute the moment matrix G for the entire domain, one should loop over every element and elemental node. However, with JAX, one can simply parallelize this “for loop” by running

Gs=jax.vmap(compute_moment_matrix)(y) (28)

where y is the parallelized input of x and Gs is the stacked G matrix obtained from the parallel operation. For example, if the size of G matrix is 36×36 and the number of 4-node elements is 100, then the size of Gs tensor becomes 100×4×36×36. It is noted that the “vmap” parallelization works in a single GPU node. Similar to “vmap”, there is “pmap” function that can parallelize over multiple GPU nodes. In one embodiment, the present invention only used “vamp” on a single GPU, but it is possible and straightforward to use “pmap” (often mixed with “vmap”) on multiple GPUs or tensor processing unit (TPU) to further parallelize steps 3-5.

As can be inferred from the previous example, the biggest hurdle of GPU programming is the memory limit. Processors in GPU have fast access to GPU memory called device memory, but the size is limited compared to CPU memory (the state-of-the-art NVIDIA GPU A100 has 80 GB of memory). Like the previous example with 10 million elements, the parallel-computed moment matrix Gs has a size of 10⁷×4×36²≈5×10¹⁰ components. A full matrix with 50 billion double-precision values exceeds the largest GPU memory of 80 GB. Note that the size grows even further when a larger patch size s or higher polynomial order p is used. Therefore, when the size of the problem grows, the parallel operations should be divided into small serial blocks each of which sufficiently leverages available GPU memory. In FIG. 7, steps 3~5 are conducted in this way, following Algorithm 1.

Algorithm 1: Block parallel algorithm

```
Initialize the number of blocks nblock, number of elements per block nelem_per_block
Initialize C-HiDeNN shape function and derivative N_til, Grad_N_til
for iblock ← 1 to nblock do
    $N , Gran\_N = compute FEM shape function and derivative in parallel // {N}_{i} and \frac{{dN}_{i}}{dx}$
    Gs = compute assembled moment matrix in parallel
    $W , Grad\_W = compute convolution patch function and derivative in parallel // {W}_{a , p , j}^{{x}_{i}}$
$and \frac{{dW}_{a , p , j}^{{x}_{i}}}{dx}$
    N til block, Grad_N_til_block = assemble FEM shape functions with patch functions for
block
    store N_til_block, Grad_N_til_block to N_til, Grad_N_til
end for
```

The iterative solver in step 7 is also implemented on a GPU using JAX library. Improvements are needed on the iterative solver, but this is not the main theme of the current invention. As JAX can run on both CPU and GPU, there is no need to develop separate codes for CPU and GPU. By default, the iterative solver runs on GPU. However, if the problem size is so large that the GPU memory cannot store the residual vector, the code automatically converts to CPU. In addition, if a curve is labeled “CPU”, the entire program including the iterative solver is implemented on a CPU. Other than these special cases, all in-house iterative solvers run on a GPU.

In one embodiment of the present invention C-HiDeNN method enables a flexible and efficient DNN framework to solve partial differential equations.

C-HiDeNN uses constrained weights and biases to build interpolation functions, as shown in FIG. 5, and is only partially connected, which has much fewer variables than fully connected PINNs and therefore solution/training time for C-HiDeNN is much shorter than PINNs. If taking the nodes as neurons, increasing the local patch size is analogous to increasing the connectivity of neurons in DNN. As such, the C-HiDeNN is equivalent to DNN (or fully connected PINNs) when the patch size covers the entire solution domain. This is confirmed by the efficiency of C-HiDeNN that is only slightly computationally costly than FEM.

C-HiDeNN can achieve higher order interpolation without changing the degrees of freedom (DoFs). FIG. 8 shows comparison between FEM (a-c) and C-HiDeNN-FEM (d-f) with different polynomial orders (p=1, 2,4). The blue box is the element of interest A^{e}, and the red box is the elemental patch domain

$${A}_{s}^{e} .$$

In C-HiDeNN, the present invention designs and adds convolution patch functions to the finite element interpolants to make the interpolants smoother and have higher reproducing polynomial order “p” without adding more nodes. Unlike higher order FEM which uses more degrees of freedom (DoFs) to build higher order shape functions, C-HiDeNN uses basic linear elements but exploits the neighboring elements as patch domains to construct higher order/smoother shape functions. This is analogous to the varying kernel size of CNN where the size of the input is fixed.

As illustrated in FIG. 7, to have higher reproducing order, FEM must use higher order elements that have more degrees of freedom while C-HiDeNN still uses linear elements but with different patch sizes (or nodal connectivity). The number of nodes of regular mesh for a given reproducing order p is given as:

FEM (np+1)² in 2D, n×n elements

(np+1)³ in 3D, n×n×n elements (29)

C-HiDeNN (n+1)² in 2D, n×n elements

(n+1)³ in 3D, n×n×n elements (30)

For example, as shown in FIG. 7 panels (c, f), when n=8 and p=4, FEM has 35,937 nodes while C-HiDeNN has 729 nodes. Therefore, C-HiDeNN can save a huge amount of DoFs compared to higher order FEM.

### C-HiDeNN Method Enables Highly Accurate Numerical Solutions and Superior Convergence Rates.

The interpolation accuracy of C-HiDeNN and its convergence are studied by solving a 2-D Poisson's problem:

∇·(∇u(x))+b_{f}(x)=0 in Ω

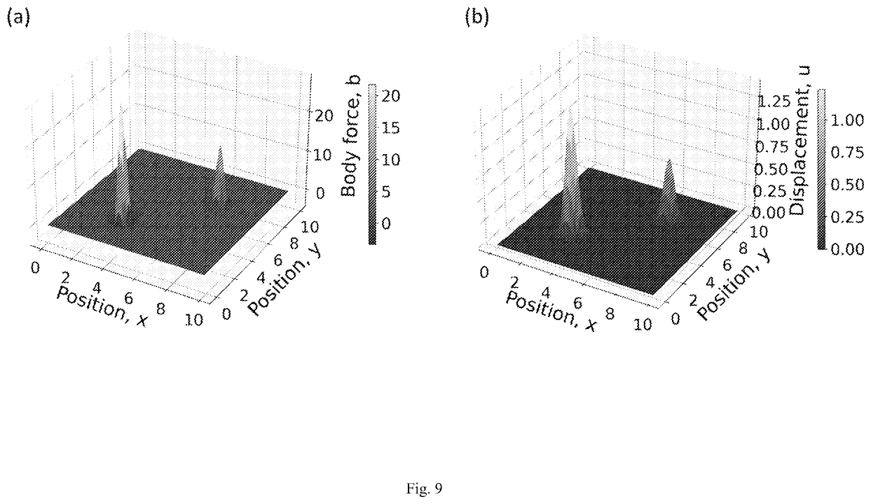

u=0 on Γ (31)

where Ω denotes a square 2-D domain whose edge length is 10, and Γ denotes the boundary of Ω. u(x) is the field variable, and b_{f}(x) is the body force. A highly stiff, double-sourced body force is assumed, and the resulting field variable is plotted in FIG. 9 along with the body force. Uniform rectangular meshes are created with different mesh size h (side length).

For error approximation, the present invention uses the L² and H¹ norm error estimators, defined as:

$${‖ e ‖}_{{L}^{2}} = {‖ u - {u}^{h} ‖}_{{L}^{2}} = \frac{{( {\int }_{Ω} {( u - {u}^{h} )}^{2} dx )}^{1 / 2}}{{( {\int }_{Ω} {u}^{2} dx )}^{1 / 2}} \qquad ( 32 )$$

$${‖ e ‖}_{{H}^{1}} = {‖ u - {u}^{h} ‖}_{{H}^{1}} = \frac{{( {\int }_{Ω} {( u - {u}^{h} )}^{2} dx + {\int }_{Ω} {‖ ∇ u - ∇ {u}^{h} ‖}_{2}^{2} dx )}^{1 / 2}}{{( {\int }_{Ω} {u}^{2} dx + {\int }_{Ω} {‖ ∇ u ‖}_{2}^{2} dx )}^{1 / 2}} \qquad ( 33 )$$

The rate of convergence depends on the reproducing polynomial order, p. In C-HiDeNN, one can arbitrarily set p by setting proper patch size s. In one embodiment, the present invention has numerically checked that to have a stable convolution patch function, that is, to solve Eq. (11) without any numerical error, s needs to be greater than or equal to p. In other words, for larger p, larger s (higher nodal connectivity) is needed.

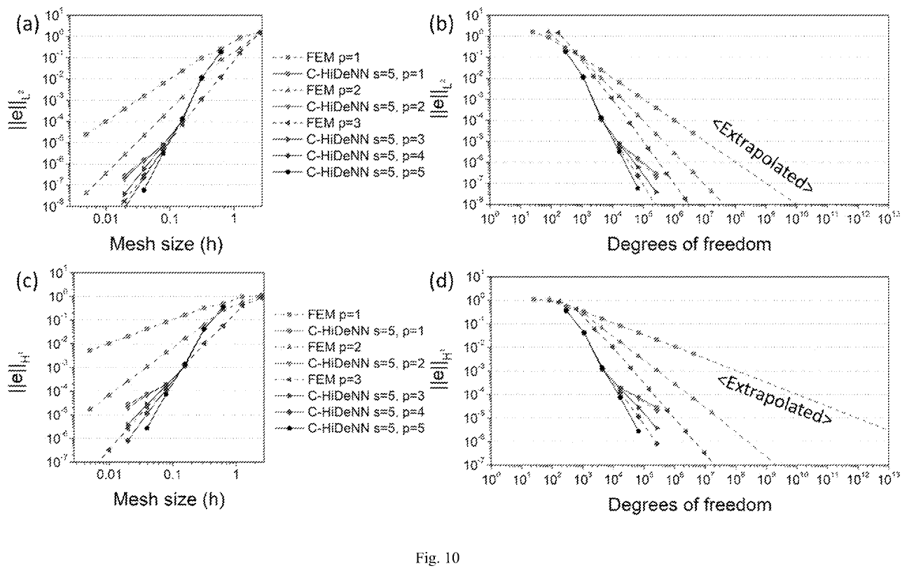

FIG. 10 shows convergence plots for uniform meshes. Panel (a, b) are for L₂ norm error and panel (c, d) are for H1 norm error estimation. Panel (a, c) are the error vs. mesh size plots and panel (b, d) are the error vs. degrees of freedom plots. For C-HiDeNN, patch size s=5 and dilation parameter a=30. The graphs are colored by the reproducing polynomial order p. FEM is depicted with dashed lines and C-HiDeNN with solid lines. The FEM curves on panel (b, d) are extrapolated at large DOFs. For the convergence study shown in FIG. 10, it is set that s=5 and p is varied from 1 to 5. The dilation parameter was set as a=30. To compare with C-HiDeNN, higher order FEM was also studied. One solved linear (p=1), quadratic (p=2), and cubic (p=3) FEM.

TABLE 3
Convergence rate of L₂ (H₁) error estimation for uniform meshes. log(∥e∥)~log(C) +
klog(h) where C, k are constants and h is the mesh size. Linear FEM (p =
1) and all C-HiDeNN cases use 4-node elements while quadratic FEM (p = 2) and
cubic FEM (p = 3) use 9-node and 16-node elements, respectively.

| Refinement | | C- | | C- | | C- | C- | C- |
|---|---|---|---|---|---|---|---|---|
| (number of | FEM | HiDeNN | FEM | HiDeNN | FEM | HiDeNN | HiDeNN | HiDeNN |
| elements) | p = 1 | s = 5, p = 1 | p = 2 | s = 5, p = 2 | p = 3 | s = 5, p = 3 | s = 5, p = 4 | s = 5, p = 5 |
| 128 × 128 | 2.00 | 2.34 | 3.00 | 2.49 | 4.00 | 3.69 | 4.39 | 5.79 |
| ~256 × 256 | (1.00) | (1.34) | (2.00) | (1.48) | (3.00) | (2.65) | (3.39) | (4.76) |
| 256 × 256 | 2.00 | 2.44 | 3.00 | 2.79 | 4.00 | 3.96 | 4.82 | — |
| ~512 × 512 | (1.00) | (1.45) | (2.00) | (1.80) | (3.00) | (2.94) | (3.83) | |

The results of the convergence study are shown in FIG. 10. Convergence rates are also given in Table 2. Overall, C-HiDeNN shows excellent solution accuracy compared to FEM. When p=1, the L² norm convergence rate of FEM is 2.00 while that of C-HiDeNN is slightly higher, 2.44. But it will eventually converge to 2.00, the theoretical convergence (same for H¹ norm error estimation). That is, the red lines in FIG. 10 panel (a, c) (dashed line for FEM and solid line for C-HiDeNN) will become parallel as the mesh refines. As shown in Table 3, when 256×256 elements (DOFs: 66,049) are used, the L² error of C-HiDeNN (p=1) is 1.29×10⁻⁶ while that of FEM (p=1) is 1.75×10⁻³; C-HiDeNN is over 10³ times more accurate than FEM.

TABLE 4
Error comparison with fixed DOFs: 66,049 (corresponds to 256 × 256, 4-node linear elements).

| | | C- | | C- | | C- | C- | C- |
|---|---|---|---|---|---|---|---|---|
| Error | FEM | HiDeNN | FEM | HiDeNN | FEM | HiDeNN | HiDeNN | HiDeNN |
| estimator | p = 1 | s = 5, p = 1 | p = 2 | s = 5, p = 2 | p = 3 | s = 5, p = 3 | s = 5, p = 4 | s = 5, p = 5 |
| ∥e∥_{L}_{²} | 1.75E−3 | 1.29E−6 | 1.70E−4* | 1.14E−6 | 2.12E−5* | 5.65E−7 | 2.27E−7 | 1.49E−7 |
| ∥e∥_{H}_{¹} | 4.39E−2 | 5.95E−5 | 4.25E−3* | 5.38E−5 | 5.59E−4* | 2.40E−5 | 9.58E−6 | 4.27E−6 |

*For higher order FEM, values are estimated from the trendlines in FIG. 10 panel (b, d).

When p=2, the convergence rate of quadratic FEM is 3.00 and 2.00 for L² and H¹ norm errors, respectively. The convergence rate of C-HiDeNN is slightly lower than that of quadratic FEM but they will converge to the theoretical values (3.00 and 2.00) as being further refined the mesh. A similar trend is observed for p=3. Note that the blue lines (p=3) in FIG. 10 panel (a, c) are close to each other. This means that the errors of cubic FEM and C-HiDeNN for the given mesh size (or the number of elements) are comparable. However, in terms of DOFs, cubic FEM is much larger than C-HiDeNN. To achieve the same level of error, FEM (p=3) needs around 10 times more DOFs than C-HiDeNN (p=3). Likewise, for the same DOFs shown in Table 3, C-HiDeNN (p=3) is over 10 times more accurate than cubic FEM.

One can achieve even faster convergence rates and higher accuracy with C-HiDeNN while still using the linear elements. When p=4 and p=5, C-HiDeNN convergence rates for L₂ and H₁ norm errors are 4.82 and 5.79, respectively. Note that for p=5, after 512×512 elements, the convergence rate starts to diverge from the theoretical trend because the moment matrix solver for Eq. (11) touches the machine error, as shown in Table 2. It is also given in Table 3 that C-HiDeNN (p=5) is around 10⁴ times more accurate than linear FEM although they are using the same mesh. A similar trend was observed from non-uniform meshes. More results on the non-uniform mesh can be found in Appendix C.

The Accuracy of Coarse Mesh is Dominated by the Patch Size “s”, while that of Fine Mesh is Dominated by the Polynomial Order “p”.

In FIG. 10 panel (a, c), C-HiDeNN curves with different reproducing order p show negligible differences for mesh sizes larger than 0.1 (64×64 elements). That is, for these coarse meshes, the radial basis function mostly contributes to the interpolation accuracy, while the polynomial order p has negligible impact. Therefore, the patch size s dominates the accuracy. As all C-HiDeNN curves use s=5, their behaviors are almost identical. Starting from 128×128 elements, the C-HiDeNN curves begin to asymptotically follow the slop defined by the reproducing order p. For this reason, one needs to carefully choose s and p to get the most efficient numerical results from C-HiDeNN. The following sections will discuss this issue more in depth.

### With Non-Uniform Mesh, C-HiDeNN can Also Achieve Highly Accurate Numerical Solutions and Superior Convergence Rates

A non-uniform mesh is created by adding random noise to a uniform mesh except the boundary nodes. This operation can be written as:

$${x}_{iI}^{non - uni} = {x}_{iI}^{uni} + h \cdot 𝒩 ( 0 , 0.1 ) \qquad ( C1 )$$

$$i = 1 , 2 for 2 D and 1 , 2 , 3 for 3 D$$

$$I ∉ Γ$$

where

$${x}_{iI}^{uni} and {x}_{iI}^{non - uni}$$

are the i-directional coordinate of node I for uniform mesh and non-uniform mesh, respectively. [symbol] (0,0.1) is a random variable that follows a normal distribution whose mean and standard deviation are 0 and 0.1, respectively. h is the side length of the uniform element and I denotes the element boundary.

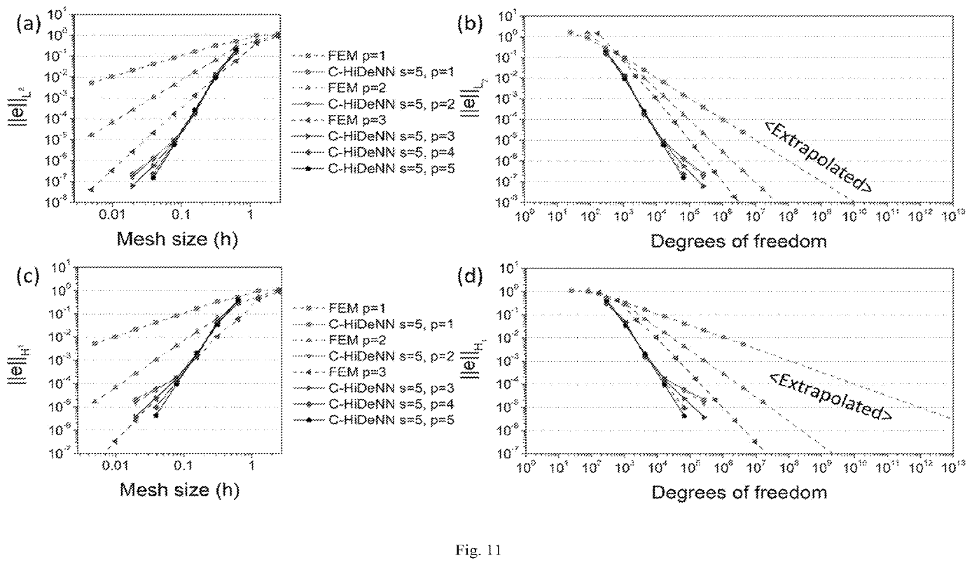

FIG. 11 shows the result of the convergence study for non-uniform meshes and Table C1 gives the corresponding convergence rates. In particular, FIG. 11 reflects convergence plots for non-uniform meshes. Panel (a, b) are for L₂ norm error and panel (c, d) are for H₁ norm error estimation. Panel (a, c) are the error vs. mesh size plots and panel (b, d) are the error vs. degrees of freedom plots. For C-HiDeNN, patch size s=5 and dilation parameter a=30. The graphs are colored by the reproducing polynomial order p. FEM uses dashed lines and C-HiDeNN uses solid lines. In general, both the convergence plot and the convergence rate follow the similar trend observed in FIG. 10 and Table 2. This implies that a non-uniform mesh does not deteriorate the approximation accuracy. This is true because the convolution patch function is built on the physical coordinates. If it is built on the natural coordinates where the nodes are equally spaced, the interpolation may miss the information of non-uniformly spaced nodal coordinates. As the convolution patch function is built on physical coordinates, the C-HiDeNN works well for both uniform and non-uniform meshes.

When Implemented on GPU Programming, C-HiDeNN Becomes More Efficient than FEM for Large DoFs Problems.

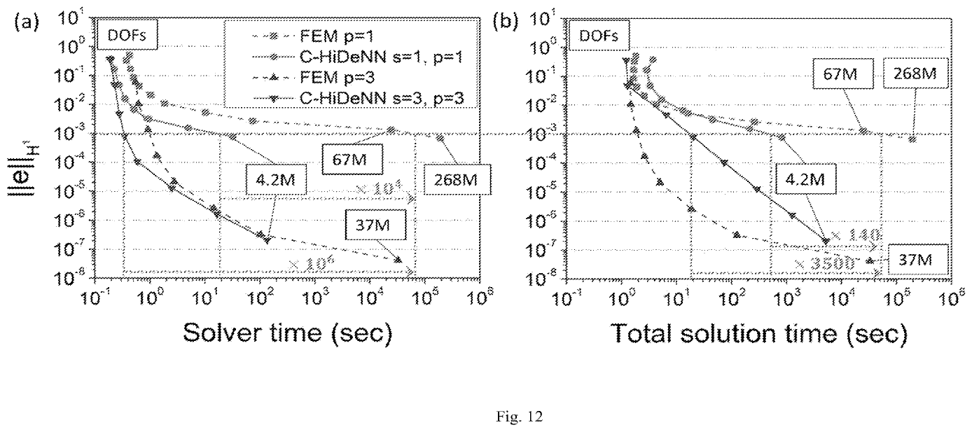

FIG. 12 shows H1 norm error vs. computation time plots for a 2-D Poisson's problem. Panel (a) is the solver time using Jacobi-preconditioned conjugate gradient iterative method, and panel (b) is the total solution time. Total solution time=shape function building time+solver time. The graphs are colored by the reproducing polynomial order p. FEM uses dashed lines and C-HiDeNN uses solid lines. Data labels denote the degrees of freedom (DOFs). FEMs with over 10 million DOFs (37M, 67M, and 268M) are solved with CPU because of the GPU memory limit. The others are solved with GPU. The speedup of computation time between C-HiDeNN and linear FEM (p=1) given 10⁻³ H1 norm error is marked with green color. Computing resources are CPU: Intel i7-10750H, GPU: NVIDIA A6000, 48 GB memory.

In general, the accuracy is inversely proportional to the computation time, which is also observed in FIG. 11 for a 2-D Poisson's problem. In FIG. 11 panel (a), the iteration solver time of C-HiDeNN is always less than that of FEM with the same reproducing order p for a given accuracy. Especially, as the error goes down, higher order FEM requires extremely large DOFs compared to C-HiDeNN with the same reproducing order p, resulting in an enormous growth of solver time. For example, 10⁻³ H1 norm requires around 100 million DOFs for FEM (p=1) while C-HiDeNN (s=1, p=1) only needs 4.2 million DOFs. It is noted that FEMs with over 10 million DoFs cannot even be solved with a GPU, as the residual vector in the iterative solver exceeds the GPU memory limit; CPU was used instead. Therefore, the solver time of C-HiDeNN (s=1, p=1) is around 104 times faster than FEM (p=1) as shown in FIG. 11 panel (a). The speedup further accelerates as one increases the order of C-HiDeNN. 10⁻³ H1 norm error can be achieved with only 16K DOFs of C-HiDeNN (s=3,p=3) even though they (linear FEM and C-HiDeNNs) are all using the same 4-node linear elements. The speedup is now around 10⁶ times.

Comparing the iterative solver time only might be too optimistic as C-HiDeNN spends considerable effort on computing shape functions (especially the convolution patch functions). In this regard, FIG. 11 panel (a) is re-drawn in FIG. 11 panel (b) in terms of the total solution time, which is a summation of the shape function building time and the solver time. Going back to the previous example of 10⁻³ H1 norm error, the speedup of C-HiDeNN (s=1, p=1) and C-HiDeNN (s=3, p=3) are around 140 and 3,500 times, respectively (see FIG. 11 panel (b)). Still, these are more than two orders of magnitude improvement in computational efficiency. It is noted that one only has exploited a single GPU (NVIDIA A6000) in this work. If one can use multiple GPUs or TPU, the shape function building time can be further reduced while it is doubtful if multiple GPUs can speed up the iterative solver time significantly.

Another important observation from FIG. 11 panel (b) is that C-HiDeNN (s=3, p=3) is around 100 times slower than cubic FEM (p=3) for an error range of 10⁻⁶~10⁻⁴, but the gap narrows as the error reduces (or problem size increases) because the solver time dominates the entire computation time for extremely large DOFs problems. Therefore, C-HiDeNN becomes more efficient than higher order FEM for problems with extremely large DOF (greater than 10 million).

### C-HiDeNN Method Provides C^{N} Continuity for the Convolved Interpolant and Solutions.

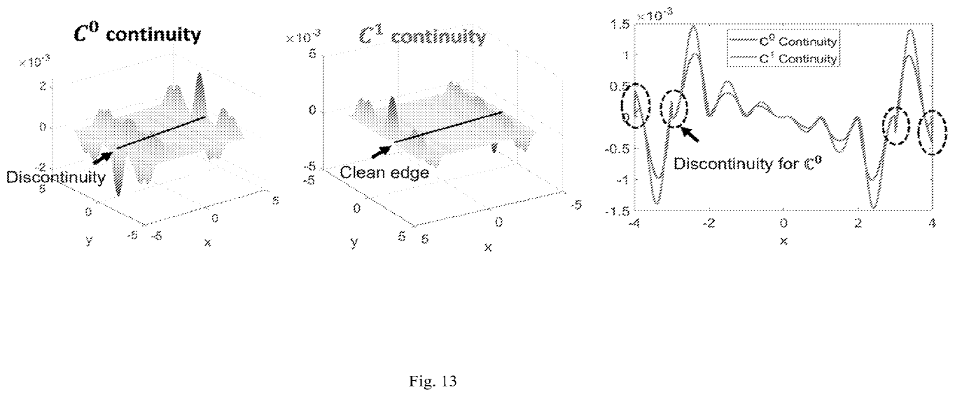

The C-HiDeNN solutions have higher order smoothness over the entire computational domain by modifying the corresponding interpolation functions. An example of C¹ is illustrated in FIG. 13 with comparison to traditional C⁰ continuity given by traditional finite element.

### C-HiDeNN can Remove Locking Regardless of Element Type.

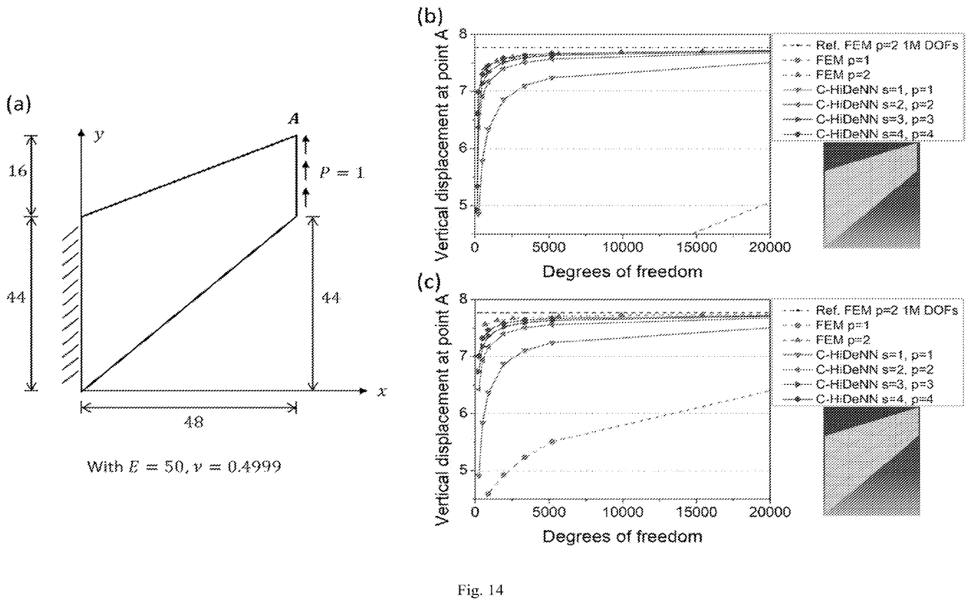

FIG. 14 shows in panel (a) 2-D Cook's membrane problem with geometric dimension, boundary condition, and material properties. Vertical displacement at upper-right tip (point A) is plotted against DOFs using quadrilateral mesh (b) and triangular mesh (c). A reference solution computed from Abaqus (p=2, quadrilateral elements, ~1M DOFs) is also plotted. In both panel (b) and (c), FEM results are plotted with dashed lines while C-HiDeNN results are plotted with solid lines. For FEM (p=2), bi-quadratic 8 node serendipity elements are used. All results are computed by in-house codes.

As C-HiDeNN interpolants achieve arbitrary reproducing order, it is expected to resolve locking like higher order FEM. To demonstrate this, C-HiDeNN is developed for 2-D linear elasticity, and the Cook's membrane problem is solved with plane strain condition and Poisson ratio v=0.4999. The problem is depicted in FIG. 14 panel (a) and the vertical displacement at point A in FIG. 14 panel (a) is plotted against the DOFs for quadrilateral elements panel (b) and triangular elements panel (c).

In FIG. 14 panel (b, c), the reference value (black-dashed line) is taken from quadratic FEM with one million DOF, measured as 7.7687. Regardless of the element type, linear FEM (p=1) severely underestimates the vertical displacement while quadratic FEM (p=2) shows better accuracy. On the other hand, even C-HiDeNN (p=1) shows significantly improved locking behavior compared to linear FEM (p=1) and the displacement estimation improves as s and p increase. The key reason behind this superior locking behavior of C-HiDeNN is that the convolution patch function spreads out the locking effect on the patch domain. Unlike linear FEM where the linear shape functions interpolate nodal variables inside an element, C-HiDeNN interpolates patch domains (neighboring elements) with higher smoothness, resulting in the unlock of elementwise stiffness.

It is also noted that for quadrilateral elements, C-HiDeNN (p=4) is as good as quadratic FEM (p=2) while the quadratic FEM (p=2) is the best for triangular elements. In addition, triangular elements are better at removing locking for this problem, because it also has a shear locking feature which is not properly captured by quadrilateral elements.

FIG. 27 shows in panel (a) that 3-D block under compression problem with geometric dimension, boundary condition, and material properties. Normalized vertical displacement (displacement divided by the reference solution) plots at top center point A using hexahedral mesh and tetrahedral mesh with coarse mesh panel (b-DOFs: 1,922) and fine mesh panel (c-DOFs: 20,402). The reference solution for the vertical displacement of point A was taken from quadratic FEM (p=2) with 3.2 million DOFs, which is 0.01677.

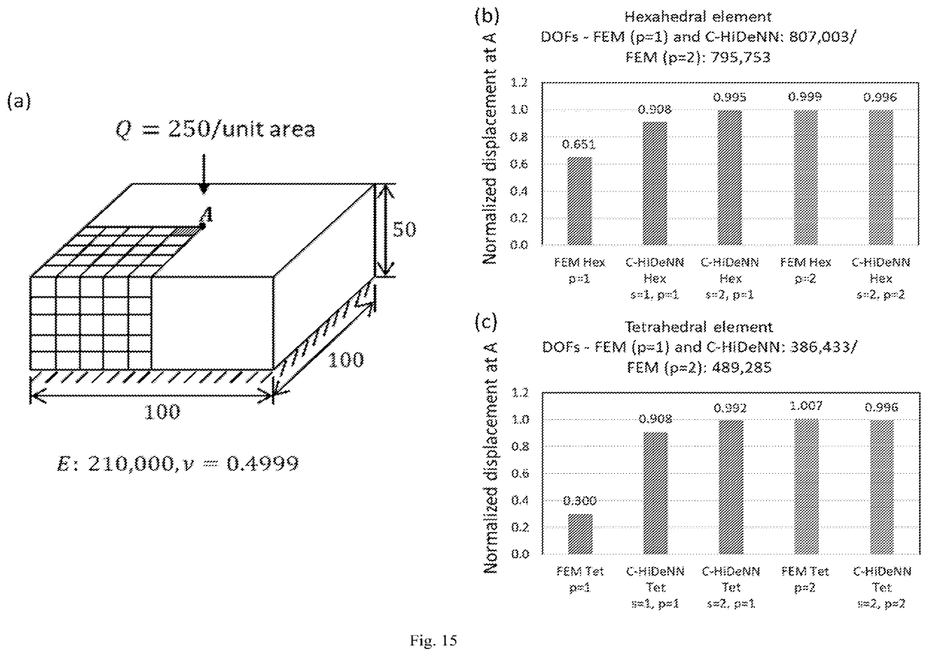

To see the locking behavior of C-HiDeNN with 3-D meshes, the 3-D block under a compression problem was solved. The problem definition is found in FIG. 15 panel (a) and the normalized displacement at the center point A is plotted in FIG. 15 panel (b hexahedral element) and FIG. 15 panel (c, tetrahedral element). Similar to the 2-D problem, C-HiDeNN removes locking for 3-D regardless of the element type: hexahedral or tetrahedral. In particular, the removal of locking with 4-node tetrahedral elements has significant potential because this element is one of the most widely used to model complex 3-D geometries. To summarize, C-HiDeNN removes locking regardless of element type and problem dimension without using special techniques such as the mixed method, selective reduced integration, and the B-bar method.

C-HiDeNN with High Performance Computing Tools Such as Graphics Processing Unit (GPU) and Message Passing Interface (MPI) can be as Fast as Conventional Numerical Software.

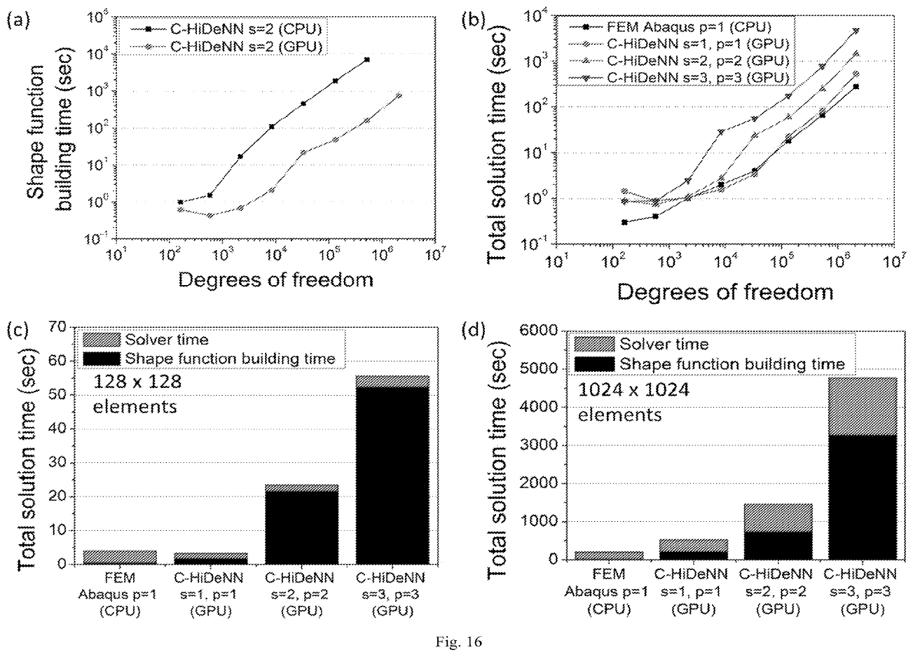

FIG. 16 shows computation time comparisons for solving a 2-D linear elastic problem. The same Cook's membrane problem described in FIG. 15 panel (a) is solved. FIG. 16 panel (a) compares the shape function building time of the same JAX code running on CPU and GPU. The CPU plot shows O(n) complexity where n is the DOFs. On the other hand, for GPU, the computation time does not grow until 10³ DOFs and then starts to grow with O(n) for larger DOFs. This is because the GPU memory can handle all parallel operations simultaneously for small DOFs, but not for larger DOFs. For these cases, even GPU programs should run in a serial manner, that is, compute shape functions for some number of elements and repeat until it covers the entire elements. Therefore, as DOFs increase, the CPU and GPU curves proceed in parallel with around ×100 speed-up for GPU.

In FIG. 16 panel (b), the total solution time of C-HiDeNN running on GPU is compared with that of Abaqus running on CPU. All curves show O(n) complexity for large DOFs. When s=1, C-HiDeNN is as fast as Abaqus, but the former (C-HiDeNN, s=1, p=1) is around 1,000 times more accurate than the latter (FEM, p=1) according to Table 4. In general, as the patch size increases by one, the computation time increases by a factor of three. There are two major reasons for this slowdown: 1) a larger patch size increases the memory size of arrays used in parallel operation, resulting in more serial iterations; 2) a larger patch size increases the bandwidth of the global stiffness matrix, resulting in heavier matrix-vector multiplication inside the iterative solver.

One can break down the total solution time displayed in FIG. 16 panel (b) into the times taken for building the shape function and for solving the system of linear equations. FIG. 16 panel (c) and (d) show this break down at 128×128 elements and 1024×1024 elements, respectively. It is notable that the relative portion of the solver time in the total solution time is less significant for small DOFs (FIG. 16 panel (c)), but the portion grows considerably for large DOFs (FIG. 16 panel (d)). This is consistent with FIG. 12, where the iterative solver time dominates the total solution time for extremely large DOF problems. Therefore, further code optimization is needed on both the shape function builder and the iterative solver to speed up the current version of C-HiDeNN.

Training in C-HiDeNN; r-Adaptivity. C-HiDeNN Automatically Updates Nodal Coordinates to Capture the Stress Localization More Efficiently

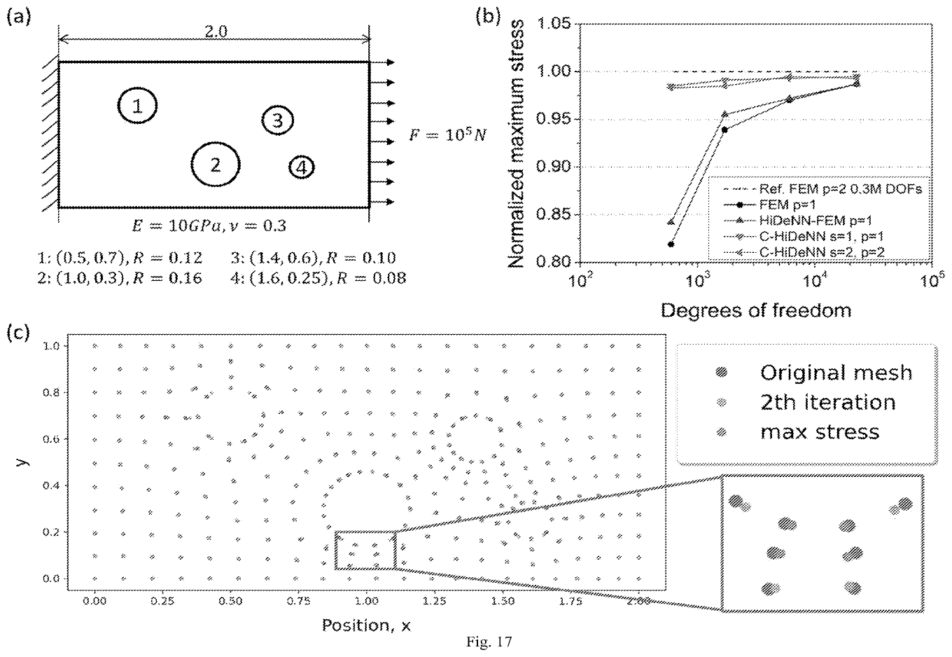

To study the effect of automatic node adaptivity, a 2-D stress concentration problem was solved, which is shown in FIG. 17 panel (a). There are four circular holes inside a 2-D plate and a horizontal force is acting on the right edge of the plate. The maximum von-Mises stress is found at the bottom of circle 2 (FIG. 17 panel (c)) and the normalized maximum von-Mises stress is plotted against DOFs in FIG. 17 panel (b). For comparison, HiDeNN-FEM (p=1) is also computed. For all cases, meshes are updated twice with fixed learning rates of 1.0 and 0.15 for HiDeNN-FEM and C-HiDeNN, respectively.

As shown in FIG. 17 panel (b), linear FEM (p=1) severely underestimates the maximum stress, especially when a coarse mesh is used. HiDeNN-FEM (p=1) estimates the maximum stress slightly better than the linear FEM, but still the coarsest mesh (~10³ DOFs) considerably underestimates the maximum stress. On the other hand, C-HiDeNN measures the maximum stress less than 2% of error with even the coarsest mesh. There are two reasons behind this: 1) r-adaptivity and 2) smooth interpolation. The adaptive node placements are visualized in FIG. 17 panel (c) and this figure clearly shows the nodes are moving toward the stress peak, the bottom of circle 2.

The present invention mentions the difficulty of selecting the most appropriate learning rate and iteration counts. As the potential energy is, in general, a non-convex function of nodal coordinates, the optimization might become ill-posed as one keeps refining the mesh or chooses a large learning rate. As they are problem dependent, further study is needed for finding adequate mesh update strategies.

C-HiDeNN can Solve Nonlinear Solid Mechanics Problems Better than FEM.

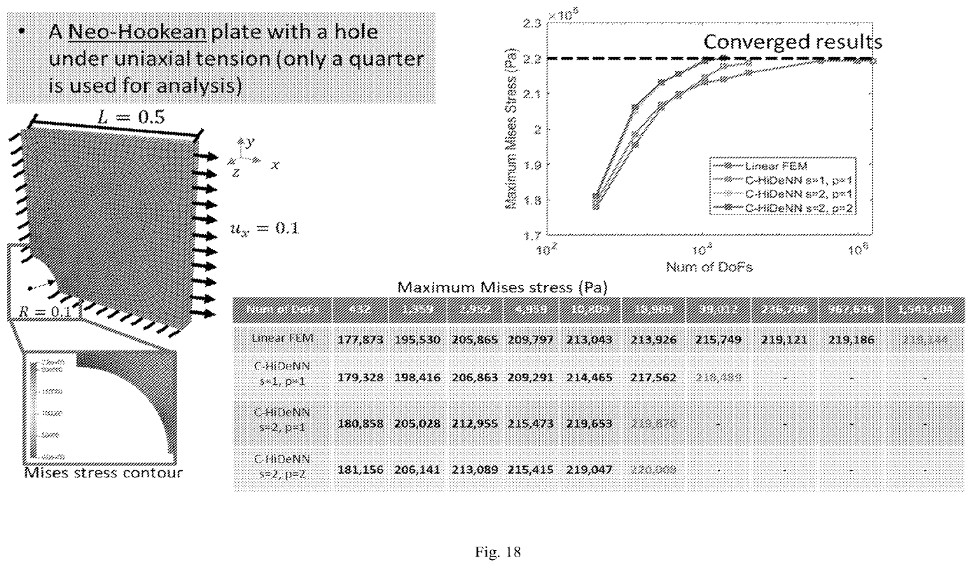

As C-HiDeNN is a general numerical solver, it can be applied to all problems where FEM can solve. The present invention solved a hyperelasticity problem shown in FIG. 18, which is a nonlinear solid mechanics problem. Compared to linear FEM, C-HiDeNN can capture the stress peak with smaller DoFs, in other words, the maximum Mises stress of C-HiDeNN converges faster than linear FEM toward the converged solution.

C-HiDeNN can Interpolate Discontinuous Nonlinear Functions, Typically Observed from Damage/Fracture Simulations

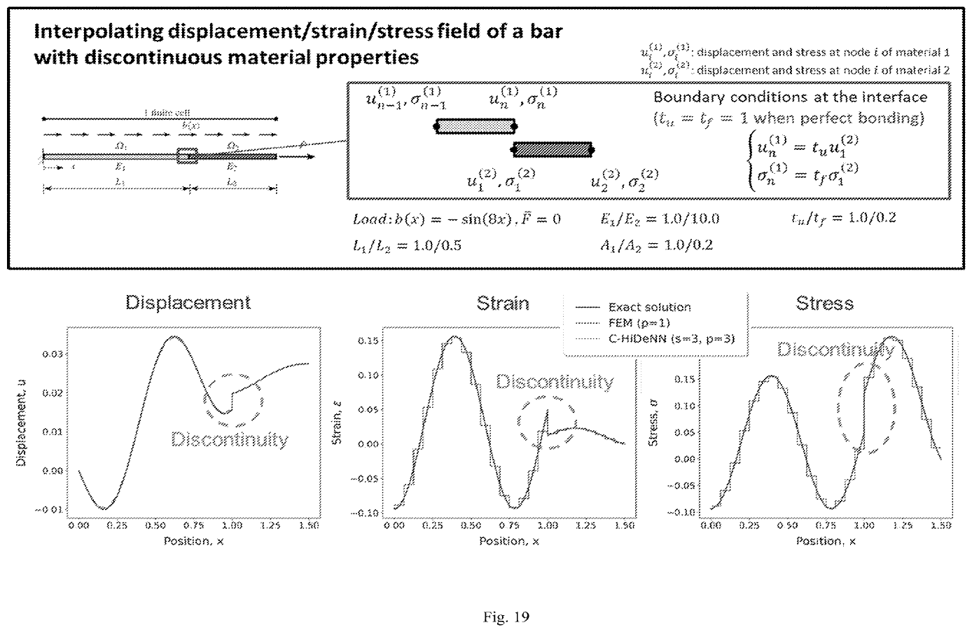

FIG. 19 shows the expected jump in the displacement and strain with the incorporation of an imperfect interfacial bonding of the coated materials system. In one embodiment, the present invention uses the simplified mechanistic model (denoted in the blue box in FIG. 13) with C-HiDeNN to capture the displacement (and strain) singularity. The simplified mechanistic model imposes one displacement boundary condition and one traction boundary condition with imperfection coefficients, tᵤ and t_{f}, respectively. As a result, all three solution fields have singularities at the interface. C-HiDeNN outperforms linear FEM and accurately predicts the exact solution. Throughout these three 1D examples, the present invention has demonstrated the capability of C-HiDeNN on modeling singularities of multi-material systems with imperfect interfacial bonding. The program can be applied to 2D and 3D damage/fracture problems.

### C-HiDeNN for Solving Fluid/Thermal Problems

When faced with problems governed by unknown equations in fluid and thermal problems, C-HiDeNN can be transformed into a specific variant: C-HiDeNN-Graph Neural Network (GNN). While conventional research on employing GNNs in physical modeling often emphasizes intricate neural structures or the incorporation of PDEs, they sometimes falter by violating conservation laws or generating unrealistic solutions. By incorporating numerical method principles with GNNs, the weights and bias in C-HiDeNN-GNN are restricted into a smaller function space.

C-HiDeNN-GNN includes three steps for modeling complex thermal and fluid problems: 1) compute the exchange fluxes/messages

$${m}_{i , j}^{t}$$

between two neighboring nodes

$${v}_{i}^{t} , {v}_{j}^{t}$$

at t time step:

$${m}_{i , j}^{t} = {f}_{{NN}_{1}} ( {v}_{i}^{t} , {v}_{j}^{t} , {e}_{i , j}^{t} ) . {e}_{i , j}^{t}$$

is the edge attributes between node i and node j. 2) combine all the neighboring fluxes/messages:

$${m}_{i}^{t} = {\sum }_{j = 1}^{Q} {m}_{i , j}^{t} .$$

3) update the current state of node i:

$${v}_{i}^{t + 1} = {v}_{i}^{t} + {f}_{{NN}_{2}} ( {v}_{i}^{t} , {m}_{i}^{t} ) .$$

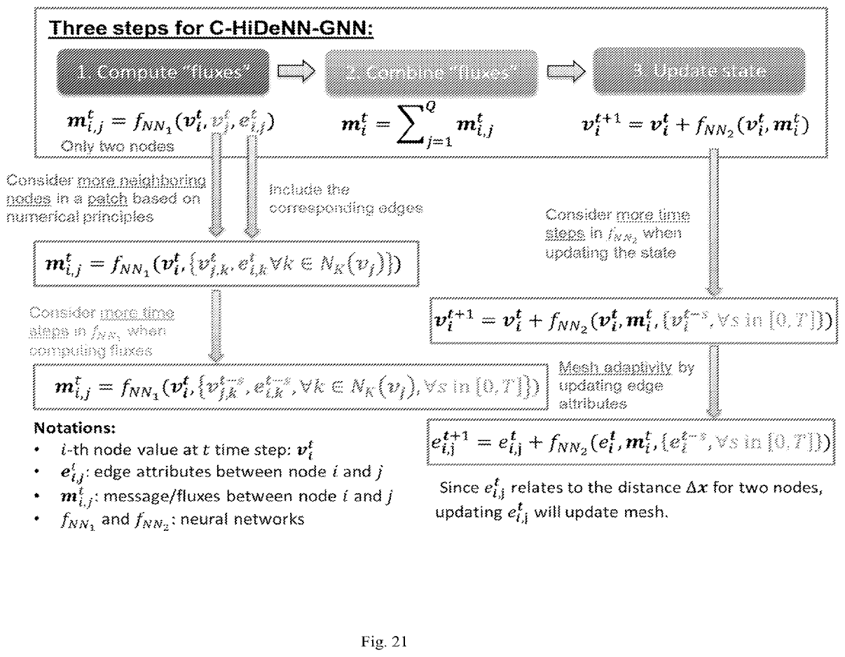

During these three steps, we apply two separate Neural Networks f_{NN}_{₁} and f_{NN}_{₂} for computing the flux and update the state. Additionally, C-HiDeNN-GNN can be easily adapted to account for a greater number of neighboring nodes (larger patches) and consecutive time steps, which are shown in FIG. 21.

The advantages of C-HiDeNN-GNN include improved accuracy, enhanced robustness, and broader applicability. This is accomplished by integrating more neighboring nodes from a designated “patch” for consistent flux calculations and applying numerical tenets to ensure physically valid solutions. Despite maintaining the same degree of freedom, the resultant model outperforms in terms of accuracy and convergence, benefiting from high-order discretization schemes derived from data. This innovative approach holds promise for breakthroughs in multiscale modeling, advanced manufacturing simulations, and high-fidelity topology optimization.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the invention pertains without departing from its spirit and scope. Accordingly, the scope of the invention is defined by the appended claims rather than the foregoing description and the exemplary embodiments described therein.

Some references, which may include patents, patent applications and various publications, are cited and discussed in the description of this invention. The citation and/or discussion of such references is provided merely to clarify the description of the invention and is not an admission that any such reference is “prior art” to the invention described herein. All references cited and discussed in this specification are incorporated herein by reference in their entireties and to the same extent as if each reference was individually incorporated by reference.

What is claimed is:

1. A forward engineering analysis method of Convolution-Hierarchical Deep-learning Neural Network (C-HiDeNN), comprising:
providing a Hierarchical Deep-learning Neural Network-Finite Element Method (HiDeNN-FEM) function;
obtaining a convolution patch function;
integrating the convolution patch function with the HiDeNN-FEM function to generate a C-HiDeNN interpolant;
obtaining an optimization problem with a physics-based loss function using the C-HiDeNN interpolant, and
resolving the optimization problem with an optimization algorithm or at least one matrix solver;
wherein linear interpolation space of the HiDeNN-FEM function is expanded to non-linear or arbitrary functions.

2. The forward engineering analysis method of C-HiDeNN of claim 1, wherein the HiDeNN-FEM function is a custom-designed neural network having a mathematical form, wherein the mathematical form comprises a partition of unity (POU)-FEM or a POU-meshfree method.

3. The forward engineering analysis method of C-HiDeNN of claim 1, wherein the convolution patch function is computed via a meshfree technique.

4. The forward engineering analysis method of C-HiDeNN of claim 3, wherein the meshfree technique comprises at least one of reproducing kernel element method (RKEM), hierarchical enrichment, radial point interpolation method (RPIM), and reproducing kernel peridynamics.

5. The forward engineering analysis method of C-HiDeNN of claim 1, wherein: the convolution patch function is obtained according to nodal connectivity and a calculation parameter.

6. The forward engineering analysis method of C-HiDeNN of claim 5, wherein the nodal connectivity is computed using graph theory.

7. The forward engineering analysis method of C-HiDeNN of claim 5, wherein the calculation parameter comprises a patch size s, a dilation parameter a, and reproducing order p.

8. The forward engineering analysis method of C-HiDeNN of claim 7, wherein the patch size s is a positive integer and is greater than or equal to p/2.

9. The forward engineering analysis method of C-HiDeNN of claim 7, wherein the dilation parameter a is a positive real number [symbol] ⁺.

10. The forward engineering analysis method of C-HiDeNN of claim 7, wherein the reproducing order p is a positive integer.

11. The forward engineering analysis method of C-HiDeNN of claim 1, wherein the computation of the HiDeNN-FEM function, convolution patch function, C-HiDeNN interpolants are parallelizable.

12. The forward engineering analysis method of C-HiDeNN of claim 1, wherein the optimization algorithms and matrix solvers are parallelizable.

13. A method for graphics processing units (GPU) programming of Convolution-Hierarchical Deep-learning Neural Network (C-HiDeNN), comprising:
(1) providing a mesh to obtain a Hierarchical Deep-learning Neural Network-Finite Element Method (HiDeNN-FEM) interpolant based on the mesh;
(2) computing an elemental patch information and a nodal connectivity based on the mesh and graph theory;
(3) computing an assembled moment matrix G using elemental patch information and a calculation parameter;
(4) obtaining a convolutional patch function based on the steps (2) and (3);
(5) integrating the convolution patch function with the HiDeNN-FEM interpolant obtained in the step (1) to generate a C-HiDeNN interpolant;
(6) building a global linear system of equations Ax=b using the C-HiDeNN interpolant; and
(7) solving the global linear system of equations using a matrix solver.

14. The method for GPU acceleration of claim 13, wherein the step (2) is accelerated with a sparse matrix programming library.

15. The method for GPU acceleration of claim 13, wherein the steps (1) and (3)-(7) are parallelized.

16. The method for GPU acceleration of claim 15, wherein the steps (3)-(6) are serially conducted and stacked in a GPU memory having a memory limit; wherein the parallelized steps (3)-(6) comprises at least one variables having a variable size; and wherein when the variable size exceeding the memory limit of GPU, the steps (3)-(6) are serially conducted and stacked in a CPU memory.

17. The method for GPU acceleration of claim 13, wherein the global linear system of equations in step (6) is obtained by linearizing a weak-form of a partial differential equation.

18. A non-transitory tangible computer readable medium storing a program which, when executed by one or more processors, causes a computer to execute a process for forward engineering analysis using Convolution-Hierarchical Deep-learning Neural Network (C-HiDeNN), the process comprising:
providing a Hierarchical Deep-learning Neural Network-Finite Element Method (HiDeNN-FEM) function;
obtaining a convolution patch function;
integrating the convolution patch function with the HiDeNN-FEM function to generate C-HiDeNN interpolants; and
obtaining an iterative solver using the C-HiDeNN interpolants;
wherein linear interpolation space of the HiDeNN-FEM function is expanded to non-linear or arbitrary functions.

19. The non-transitory tangible computer readable medium storing a program causing a computer to execute a process for forward engineering analysis using C-HiDeNN of claim 18, wherein the convolution patch function is controlled by a patch size s, a dilation parameter a, and reproducing order p.

20. A non-transitory tangible computer readable medium storing a program which, when executed by one or more processors, causes a computer to execute a process for GPU acceleration using Convolution-Hierarchical Deep-learning Neural Network (C-HiDeNN), the process comprising:
(1) providing a mesh to obtain a Hierarchical Deep-learning Neural Network-Finite Element Method (HiDeNN-FEM) interpolant based on the mesh;
(2) computing an elemental patch information and a nodal connectivity based on the mesh and graph theory;
(3) computing an assembled moment matrix G using elemental patch information and a calculation parameter;
(4) obtaining a convolutional patch function based on the steps (2) and (3);
(5) integrating the convolution patch function with the HiDeNN-FEM interpolant obtained in the step (1) to generate a C-HiDeNN interpolant;
(6) building a global linear system of equations Ax=b using the C-HiDeNN interpolant; and
(7) solving the global linear system of equations using a matrix solver.

21. The forward engineering analysis method of C-HiDeNN of claim 1, wherein the step of resolving the optimization problem comprises training the optimization problem with the optimization algorithm or the at least one matrix solver.

22. The forward engineering analysis method of C-HiDeNN of claim 1, wherein the step of resolving the optimization problem comprises solving the optimization problem with the optimization algorithm or the at least one matrix solver.
